(19) United States
(12) Patent Application Publication
(10) Pub. No.: US 2025/0372169 A1
(43) Pub. Date: Dec. 4, 2025

(54) MEMORY DEVICE INCLUDING CONDUCTIVE CONTACTS ALIGNED WITH SUPPORT STRUCTURES

(71) Applicant: Micron Technology, Inc., Boise, ID (US)

(72) Inventors: Justin David Shepherdson, Meridian, ID (US); John Mark Meldrim, Boise, ID (US); Sidhartha Gupta, Boise, ID (US); Yucheng Wang, Meridian, ID (US); Matthew J. King, Boise, ID (US)

(21) Appl. No.: 19/224,161

(22) Filed: May 30, 2025

Related U.S. Application Data
(60) Provisional application No. 63/654,578, filed on May 31, 2024.

(51) Int. Cl. G11C 16/04; G11C 5/06; H01L 21/768; H10B 41/10; H10B 41/27; H10B 43/10; H10B 43/27

(52) U.S. Cl. CPC G11C 16/0483; G11C 5/063; H01L 21/76843; H01L 21/76879; H10B 41/10; H10B 41/27; H10B 43/10; H10B 43/27

(57) ABSTRACT

Some embodiments include apparatuses and methods of forming the apparatuses. One of the apparatuses includes a memory device, which includes: levels of conductive materials interleaved with levels of dielectric materials; memory cell strings including respective pillars extending through the levels of conductive materials and the levels of dielectric materials; a dielectric structure including a length extending through the levels of conductive materials and the levels of dielectric materials; and a conductive contact contacting one of the levels of conductive materials. The conductive contact includes a first portion and a second portion, and the dielectric structure includes a portion between the first portion of the conductive contact and the second portion of the conductive contact.

### PRIORITY APPLICATION

This application claims the benefit of priority to U.S. Provisional Application Ser. No. 63/654,578, filed May 31, 2024, which is incorporated herein by reference in its entirety.

### BACKGROUND

Dimensions of structures of some of the components in a memory device (e.g., a flash memory device) are relatively small (e.g., in nanometer size). At a certain small dimension of a memory device, structural damage (e.g., collapse) in part of the memory device may occur during fabrication. Such collapse can negatively affect yield, cost, performance, and reliability of the memory device.

### BRIEF DESCRIPTION OF THE DRAWINGS

FIG. 1 shows a block diagram of an apparatus in the form of a memory device, according to some embodiments described herein.

FIG. 2 shows a general schematic diagram of a portion of a memory device including a memory array having blocks (blocks of memory cells) and sub-blocks in each of the blocks, according to some embodiments described herein.

FIG. 3 shows a detailed schematic diagram of two blocks of the memory device of FIG. 2, according to some embodiments described herein.

FIG. 4 shows a top view of a structure of a portion of the memory device of FIG. 3 including a region of a memory array, a conductive contact region, and structures between the blocks of the memory device, according to some embodiments described herein.

FIG. 5 shows a side view (e.g., cross-section) of a structure of a portion of the memory device of FIG. 4, including tiers of materials that include respective memory cells and control gates associated with the memory cells, according to some embodiments described herein.

FIG. 6A, FIG. 6B, and FIG. 6C show top views of respective portions of the structure of the memory device of FIG. 4 and FIG. 5, including conductive contacts and dielectric structures (e.g., support structures), according to some embodiments described herein.

FIG. 7 shows a side view (e.g., cross-section) of a portion of the memory device of FIG. 6A and FIG. 6B, including conductive contacts and dielectric structures, according to some embodiments described herein.

FIG. 8A, FIG. 8B, and FIG. 8C show top views (e.g., cross-sections) along lines 8A, 8B, and 8C in FIG. 7, according to some embodiments described herein.

FIG. 8D shows an enlarged portion of the side view of the memory device of FIG. 7 including a conductive contact and a dielectric structure, according to some embodiments described herein.

FIG. 9 shows a memory device that can be a variation of the memory device shown in FIG. 6A, according to some embodiments described herein.

FIG. 10A through FIG. 25B show different views of elements during processes of forming a memory device including forming conductive contacts and dielectric structures (e.g., support structures) of the memory device, according to some embodiments described herein.

FIG. 26 through FIG. 31 show side views of elements during processes of forming a memory device having multiple decks, according to some embodiments described herein.

### DETAILED DESCRIPTION

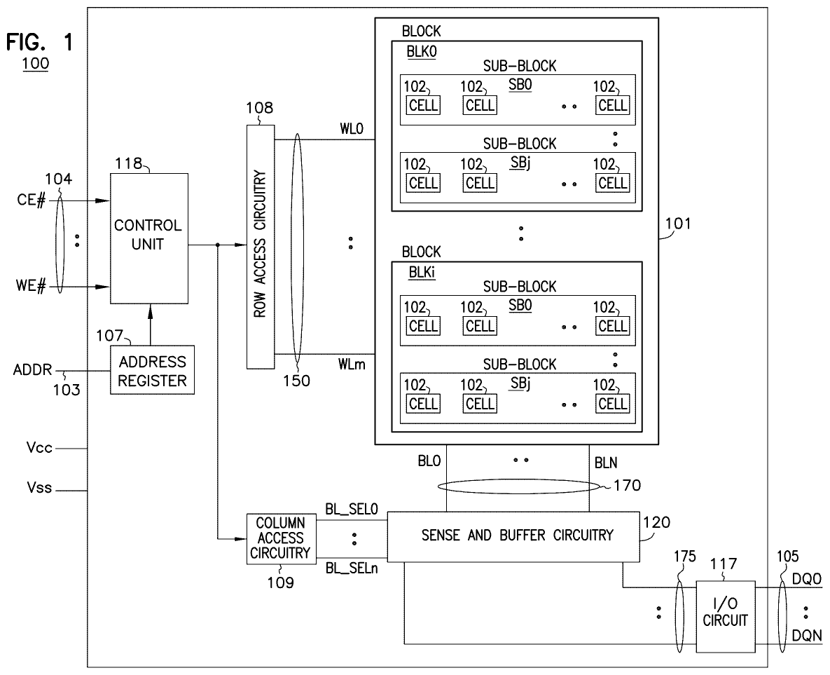

The techniques described herein involve a memory device including memory cells formed in tiers (different physical levels) of the memory device. The tiers include respective levels of conductive materials. The conductive materials form part of control gates (e.g., word lines) associated with the memory cells. The described memory device includes conductive contacts associated with the control gates. The conductive contacts are located at a region of the memory device. The region also includes part of the control gates. The memory device further includes dielectric structures (e.g., support structures) at the region where the conductive contacts are located. The dielectric structures provide structural support for part of the memory device. For example, the dielectric structures are formed to prevent damage (e.g., collapse) of part of the control gates at the region. As described in more detail below, the structure of the described memory device (e.g., the conductive contacts and the dielectric structures) improves at least one of yield, cost, performance, and reliability associated with the memory device. Other improvements and benefits of the techniques described herein are further discussed below with reference to FIG. 1 through FIG. 31.

FIG. 1 shows a block diagram of an apparatus in the form of a memory device 100, according to some embodiments described herein. Memory device 100 can include a memory array (or multiple memory arrays) 101 containing memory cells 102 arranged in blocks (blocks of memory cells), such as blocks BLK0 through BLKi. Each of blocks BLK0 through BLKi can include its own sub-blocks, such as sub-blocks SB0 through SBj. A sub-block is a portion of a block. In the physical structure of memory device 100, memory cells 102 can be arranged vertically (e.g., stacked one over another) over a substrate (e.g., a semiconductor substrate) of memory device 100.

As shown in FIG. 1, memory device 100 can include access lines (which can include word lines) 150 and data lines (which can include bit lines) 170. Access lines 150 can carry signals (e.g., word line signals) WL0 through WLm. Data lines 170 can carry signals (e.g., bit line signals) BL0 through BLn. Memory device 100 can use access lines 150 to selectively access memory cells 102 of blocks BLK0 through BLKi and data lines 170 to selectively exchange information (e.g., data) with memory cells 102 of blocks BLK0 through BLKi. Data lines can be shared among blocks BLK0 through BLKi.

Memory device 100 can include an address register 107 to receive address information (e.g., address signals) ADDR on lines (e.g., address lines) 103. Memory device 100 can include row access circuitry 108 and column access circuitry 109 that can decode address information from address register 107. Based on decoded address information, memory device 100 can determine which memory cells 102 of which sub-blocks of blocks BLK0 through BLKi are to be accessed during a memory operation. Memory device 100 can perform a read operation to read (e.g., sense) information (e.g., previously stored information) from memory cells 102 of blocks BLK0 through BLKi, or a write (e.g., programming) operation to store (e.g., program) information in memory cells 102 of blocks BLK0 through BLKi. Memory device 100 can use data lines 170 associated with signals BL0 through BLn to provide information to be stored in memory cells 102 or obtain information read (e.g., sensed) from memory cells 102. Memory device 100 can also perform an erase operation to erase information from some or all of memory cells 102 of blocks BLK0 through BLKi.

Memory device 100 can include a control unit 118 that can be configured to control memory operations of memory device 100 based on control signals on lines 104. Examples of the control signals on lines 104 include one or more clock signals and other signals (e.g., a chip enable signal CE#, a write enable signal WE#) to indicate which operation (e.g., read, write, or erase operation) memory device 100 can perform. Other devices external to memory device 100 (e.g., a memory controller or a processor) may control the values of the control signals on lines 104. Specific values of a combination of the signals on lines 104 may produce a command (e.g., read, write, or erase command) that causes memory device 100 to perform a corresponding memory operation (e.g., read, write, or erase operation).

Memory device 100 can include sense and buffer circuitry 120 that can include components such as sense amplifiers and page buffer circuits (e.g., data latches). Sense and buffer circuitry 120 can respond to signals BL_SEL0 through BL_SELn from column access circuitry 109. Sense and buffer circuitry 120 can be configured to determine (e.g., by sensing) the value of information read from memory cells 102 (e.g., during a read operation) of blocks BLK0 through BLKi and provide the value of the information to lines (e.g., global data lines) 175. Sense and buffer circuitry 120 can also be configured to use signals on lines 175 to determine the value of information to be stored (e.g., programmed) in memory cells 102 of blocks BLK0 through BLKi (e.g., during a write operation) based on the values (e.g., voltage values) of signals on lines 175 (e.g., during a write operation).

Memory device 100 can include input/output (I/O) circuitry 117 to exchange information between memory cells 102 of blocks BLK0 through BLKi and lines (e.g., I/O lines) 105. Signals DQ0 through DQN on lines 105 can represent information read from or stored in memory cells 102 of blocks BLK0 through BLKi. Lines 105 can include nodes within memory device 100 or pins (or solder balls) on a package where memory device 100 can reside. Other devices external to memory device 100 (e.g., a memory controller or a processor) can communicate with memory device 100 through lines 103, 104, and 105.

Memory device 100 can receive a supply voltage, including supply voltages Vcc and Vss. Supply voltage Vss can operate at a ground potential (e.g., having a value of approximately zero volts). Supply voltage Vcc can include an external voltage supplied to memory device 100 from an external power source such as a battery or alternating current to direct current (AC-DC) converter circuitry.

Each of the memory cells 102 can be programmed to store information representing a value of at most one bit (e.g., a single bit), or a value of multiple bits such as two, three, four, or another number of bits. For example, each of memory cells 102 can be programmed to store information representing a binary value “0” or “1” of a single bit. The single bit per cell is sometimes called a single-level cell. In another example, each of the memory cells 102 can be programmed to store information representing a value for multiple bits, such as one of four possible values “00”, “01”, “10”, and “11” of two bits, one of eight possible values “000”, “001”, “010”, “011”, “100”, “101”, “110”, and “111” of three bits, or one of other values of another number of multiple bits (e.g., more than three bits in each memory cell). A cell that has the ability to store multiple bits is sometimes called a multi-level cell (or multi-state cell).

Memory device 100 can include a non-volatile memory device, and memory cells 102 can include non-volatile memory cells, such that memory cells 102 can retain information stored thereon when power (e.g., voltage Vcc, Vss, or both) is disconnected from memory device 100. For example, memory device 100 can be a flash memory device, such as a NAND flash (e.g., 3D NAND) or a NOR flash memory device, or another kind of memory device, such as a variable resistance memory device (e.g., a phase change memory device or a resistive Random Access Memory (RAM) device).

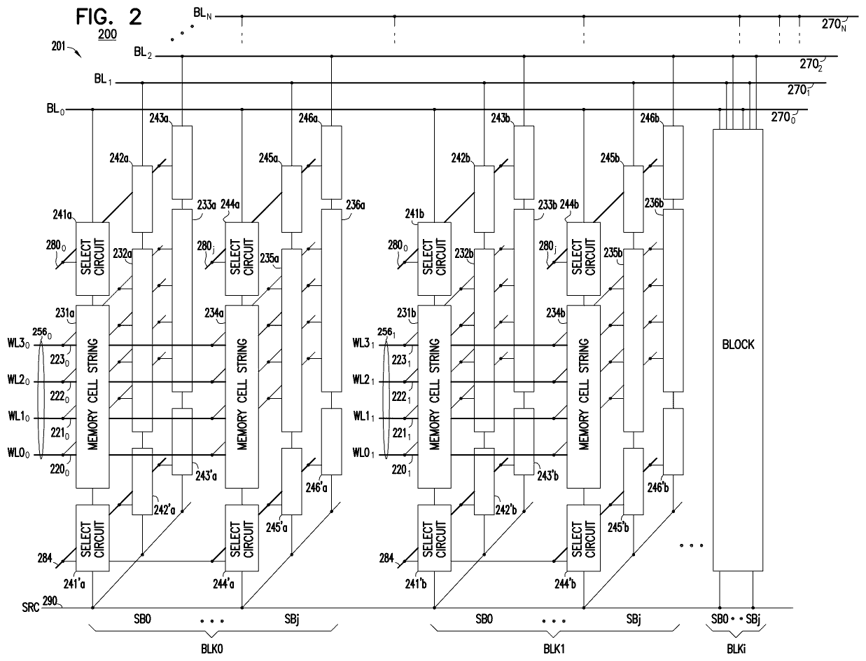

One of ordinary skill in the art may recognize that memory device 100 may include other components, several of which are not shown in FIG. 1 so as not to obscure the example embodiments described herein. At least a portion of memory device 100 can include structures and perform operations similar to or identical to the structures and operations of any of the memory devices described below with reference to FIG. 2 through FIG. 31.

FIG. 2 shows a general schematic diagram of a portion of a memory device 200 including a memory array 201 having blocks (blocks of memory cells) BLK0 through BLKi and sub-blocks SB0 through SBj in each of the blocks, according to some embodiments described herein. Memory device 200 can correspond to memory device 100 of FIG. 1. For example, memory array 201 can form part of memory array 101 of FIG. 1.

As shown in FIG. 2, each sub-block (e.g., SB0 or SBj) has its own memory cell strings that can be associated with (e.g., coupled to) respective select circuits. The sub-blocks of the blocks (e.g., blocks BLK0 through BLKi) of memory device 200 can have the same number of memory cell strings and associated select circuits. For example, sub-block SB0 of block BLK0 has memory cell strings 231a, 232a, and 233a and associated select circuits (e.g., drain select circuits) 241a, 242a, and 243a, respectively, and select circuits (e.g., source select circuits) 241′a, 242′a, and 243′a, respectively. In another example, sub-block SBj of block BLK0 has memory cell strings 234a, 235a, and 236a and associated select circuits (e.g., drain select circuits) 244a, 245a, and 246a, respectively, and select circuits (e.g., source select circuits) 244′a, 245′a, and 246′a, respectively.

Similarly, sub-block SB0 of block BLK1 has memory cell strings 231b, 232b, and 233b, and associated select circuits (e.g., drain select circuits) 241b, 242b, and 243b, respectively, and select circuits (e.g., source select circuits) 241′b, 242′b, and 243′b, respectively. Sub-block SBj of block BLK1 has memory cell strings 234b, 235b, and 236b, and associated select circuits (e.g., drain select circuits) 244b, 245b, and 246b, respectively, and select circuits (e.g., source select circuits) 244′b, 245′b, and 246′b, respectively.

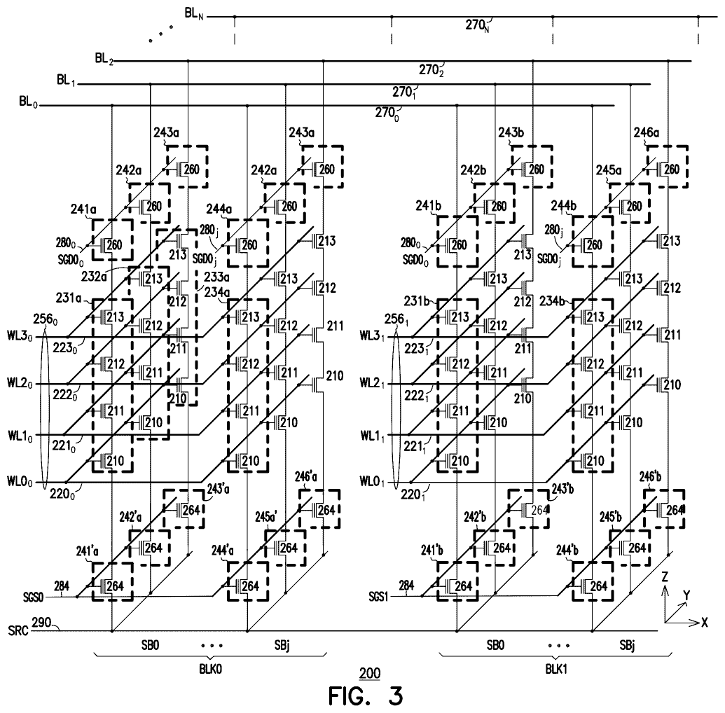

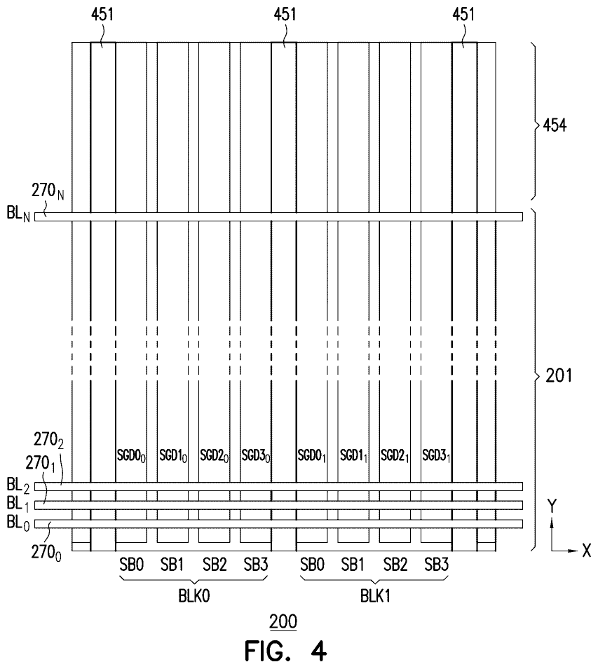

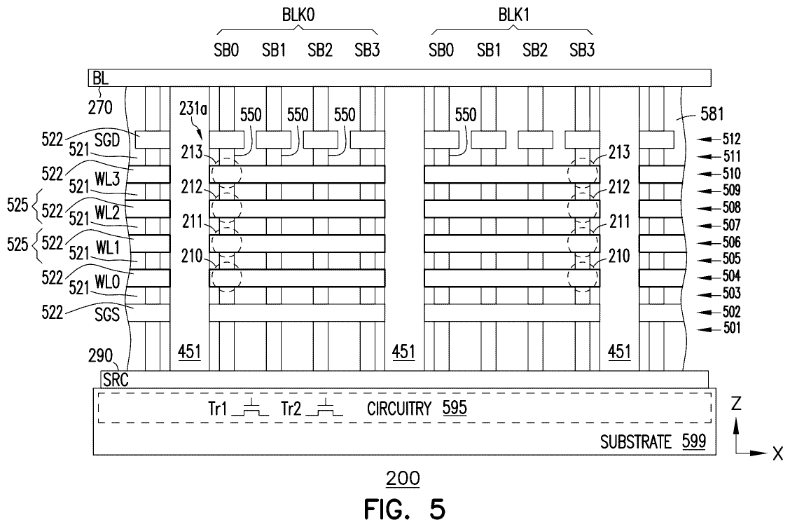

FIG. 2 shows an example of three memory cell strings and their associated circuits in a sub-block (e.g., in sub-block SB0). The number of memory cell strings and their associated select circuits in each sub-block of blocks BLK0 through BLKi can vary. Each of the memory cell strings of memory device 200 can include series-connected memory cells (shown in detail in FIG. 3 and FIG. 4) and a pillar (e.g., pillar 550 in FIG. 5) where the series-connected memory cells can be located (e.g., vertically located) along respective portion of the pillar.

As shown in FIG. 2, memory device 200 can include data lines 270₀ through 270_{N} that carry signals BL₀ through BL_{N}, respectively. Each of data lines 270₀ through 270_{N} can be structured as a conductive line that can include conductive materials (e.g., conductively doped polycrystalline silicon (doped polysilicon), metals, or other conductive materials).

The memory cell strings of blocks BLK0 through BLKi can share data lines 270₀ through 270_{N} to carry information (in the form of signals) read from or to be stored in memory cells of selected memory cells (e.g., selected memory cells in block BLK0 or BLK1) of memory device 200. For example, memory cell strings 231a, 234a (of block BLK0), 231b and 234b (of block BLK1) can share data line 270₀. Memory cell strings 232a, 235a (of block BLK0), 232b and 235b (of block BLK1) can share data line 270₁. Memory cell strings 233a, 236a (of block BLK0), 233b and 236b (of block BLK1) can share data line 270₂.

Memory device 200 can include a source (e.g., a source line, a source plate, or a source region) 290 that can carry a signal (e.g., a source line signal) SRC. Source 290 can be structured as a conductive line or a conductive plate (e.g., conductive region) of memory device 200. Source 290 can be a common source (e.g., common source plate or common source region) of blocks BLK0 through BLKi. Alternatively, each of blocks BLK0 through BLKi can have its own source similar to source 290. Source 290 can be coupled to a ground connection of memory device 200.

Each of the blocks BLK0 through BLKi can have its own group of control gates for controlling access to memory cells of the memory cell strings of the sub-block of a respective block. As shown in FIG. 2, memory device 200 can include control gates (e.g., word lines) 220₀, 221₀, 222₀, and 223₀ in block BLK0 that can be part of conductive paths (e.g., access lines) 256₀ of memory device 200. Memory device 200 can include control gates (e.g., word lines) 220₁, 221₂, 222₁, and 223₁ in block BLK1 that can be part of other conductive paths (e.g., access lines) 256₁ of memory device 200. Conductive paths 256₀ and 256₁ can correspond to part of access lines 150 of memory device 100 of FIG. 1.

As shown in FIG. 2, control gates 220₀, 221₀, 222₀, and 223₀ can be electrically separated from each other. Control gates 220₁, 221₂, 222₁, and 223₁ can be electrically separated from each other. Control gates 220₀, 221₀, 222₀, and 223₀ can be electrically separated from control gates 220₁, 221₂, 222₁, and 223₁. Thus, blocks BLK0 through BLKi can be accessed separately (e.g., accessed one at a time).

FIG. 2 shows memory device 200 including four control gates in each of blocks BLK0 through BLKi as an example. The number of control gates of the blocks (e.g., blocks BLK0 through BLKi) of memory device 200 can be different from four. For example, each of blocks BLK0 through BLKi can include up to hundreds of control gates (or more than hundreds of control gates).

Each of the control gates 220₀, 221₀, 222₀, and 223₀ can be part of a structure (e.g., a level) of a conductive material (e.g., a layer of conductive material) located in a level of memory device 200. Control gates 220₀, 221₀, 222₀, and 223₀ can carry corresponding signals (e.g., word line signals) WL0₀, WL1₀, WL2₀, and WL3₀. Memory device 200 can use signals WL0₀, WL1₀, WL2₀, and WL3₀ to selectively control access to memory cells of block BLK0 during an operation (e.g., read, write, or erase operation).

Each of control gates 220₁, 221₂, 222₁, and 223₁ can be part of a structure (e.g., a level) of a conductive material (e.g., a layer of conductive material) located in a level of memory device 200. Control gates 220₁, 221₂, 222₁, and 223₁ can carry corresponding signals (e.g., word line signals) WL0₀, WL1₀, WL2₀, and WL3₀. Memory device 200 can use signals WL0₁, WL1₁, WL2₁, and WL3₁ to selectively control access to memory cells of block BLK0 during an operation (e.g., read, write, or erase operation).

As shown in FIG. 2, in sub-block SB0 of block BLK0, memory device 200 can include a select line (e.g., drain select line) 280₀ that can be shared by select circuits 241a, 242a, and 243a. In sub-block SBj of block BLK0, memory device 200 can include a select line (e.g., drain select line) 280ⱼ that can be shared by select circuits 244a, 245a, and 246a. Block BLK0 can include a select line (e.g., source select line) 284 that can be shared by select circuits 241′a, 242′a, 243′a, 244′a, 245′a, and 246′a.

In sub-block SB0 of block BLK1, memory device 200 can include a select line (e.g., drain select line) 280₀, which is electrically separated from select line 280₀ of block BLK1. Select line 280₀ of block BLK1 can be shared by select circuits 241b, 242b, and 243b. In sub-block SBj of block BLK1, memory device 200 can include a select line (e.g., drain select line) 280ⱼ that can be shared by select circuits 244b, 245b, and 246b. Select lines 280₀ and 280ⱼ of block BLK1 are electrically separated from select lines 280₀ and 280ⱼ of block BLK0. Block BLK1 can include a select line (e.g., source select line) 284 that can be shared by select circuits 241′b, 242′b, 243′b, 244′b, 245′b, and 246′b.

FIG. 2 shows an example where memory device 200 includes one drain select line (e.g., select line 280₀) shared by select circuits (e.g., select circuits 241a, 242a, or 243a) in a sub-block (e.g., sub-block SB0 of block BLK0). However, memory device 200 can include multiple drain select lines shared by select circuits in a sub-block. FIG. 2 shows an example where memory device 200 includes one source select line (e.g., select line 284) shared by source select circuits (e.g., select circuits 241′a, 242′a, or 243′a) in a sub-block (e.g., sub-block SB0 of block BLK0). However, memory device 200 can include multiple source select lines shared by source select circuits in a sub-block.

In FIG. 2, each of the drain select circuits of memory device 200 can include a drain select gate (e.g., a transistor, shown in FIG. 3) between a respective data line and a respective memory cell string. The drain select gate (e.g., transistor) can be controlled (e.g., turned on or turned off) by a signal on the respective drain select line based on voltages provided to the signal.

In FIG. 2, each of the source select circuits of memory device 200 can include a source select gate (e.g., a transistor, shown in FIG. 3) coupled between source 290 and a respective memory cell string. The source select gate (e.g., transistor) can be controlled (e.g., turned on or turned off) by a signal on a respective source select line based on a voltage provided to the signal.

FIG. 3 shows a detailed schematic diagram including blocks of the blocks BLK0 and BLK1 of memory device 200 of FIG. 2, according to some embodiments described herein. In FIG. 3, directions X, Y, and Z in FIG. 3 can be relative to the physical directions (e.g., three dimensional (3D) dimensions) of the structure of memory device 200. For example, the Z-direction can be a direction perpendicular to (e.g., vertical direction with respect to) a substrate of memory device 200 (e.g., a substrate 599 shown in FIG. 5). The Z-direction is perpendicular to the X-direction and Y-direction (e.g., the Z-direction is perpendicular to an X-Y plane of memory device 200).

For simplicity, only some of the memory cell strings and some of the select circuits of memory device 200 of FIG. 2 are labeled in FIG. 3. As shown in FIG. 3, each select line can carry an associated separate select signal. For example, in sub-block SB0 of block BLK0, select line (e.g., drain select line) 280₀ can carry signal (e.g., drain select-gate signal) SGD0₀. In sub-block SBj of block BLK0, select line (e.g., drain select line) 280ⱼ can carry signal (e.g., drain select-gate signal) SGD0ⱼ. Sub-blocks SB0 and SBj of block BLK0 can share select line 284 that can carry signal (e.g., source select-gate signal) SGS0.

In sub-block SB0 of block BLK1, select line (e.g., drain select line) 280₀ can carry signal (e.g., drain select-gate signal) SGD0₀. In sub-block SBj of block BLK1, select line (e.g., drain select line) 280ⱼ can carry signal (e.g., drain select-gate signal) SGD0ⱼ. Sub-blocks SB0 and SBj of block BLK1 can share select line 284 that can carry signal (e.g., source select-gate signal) SGS1.

For simplicity, similar or the same elements in the memory devices (e.g., memory device 200) described herein are given the same label. For example, as shown in FIG. 3, similar drain select lines (and their associated signals) are given the same labels for simplicity. However, as shown in FIG. 3, the drain select lines (from the same block or from different blocks) of memory device 200 are electrically separated from each other and carry different signals (although the signals are given the same labels).

As shown in FIG. 3, memory device 200 can include memory cells 210, 211, 212, and 213; select gates (e.g., drain select gates or transistors) 260; and select gates (e.g., source select gates) 264 that can be physically arranged in three dimensions (3D), such as X, Y, and Z directions (e.g., dimensions), with respect to the structure (shown in FIG. 4) of memory device 200.

In FIG. 3, each of the memory cell strings (e.g., memory cell string 231a) of memory device 200 can include series-connected memory cells that include one of memory cells 210, one of memory cells 211, one of memory cells 212, and one of memory cells 213. FIG. 3 shows an example of four memory cells 210, 211, 212, and 213 in each memory cell string. The number of memory cells in each memory cell string can vary. For example, each memory string can include up to hundreds (or more) of memory cells.

As shown in FIG. 3, each drain select circuit (e.g., select circuit 241a) can include one of select gates 260. Each source select circuit (e.g., select circuit 241′a) can include one of select gates 264.

Each of select gates 260 in FIG. 3 can operate like a transistor. For example, select gate 260 of select circuit 241a can operate like a field effect transistor (FET), such as a metal-oxide semiconductor FET (MOSFET). An example of such a MOSFET include an n-channel MOS (NMOS) transistor.

A select line (e.g., select line 280₀ of sub-block SB0 of block BLK0) can carry a signal (e.g., signal SGD0₀) but it does not operate like a switch (e.g., a transistor). A select gate (e.g., select gate 260 of select circuit 241a) can receive a signal (e.g., signal SGD0₀) from a respective select line (e.g., select line 280₀ of sub-block SB0 of block BLK0) and can operate like a switch (e.g., a transistor).

In the physical structure of memory device 200, a select line (e.g., select line 280₀ of sub-block SB0 of block BLK0) can be a structure (e.g., a level) of a conductive material (e.g., a layer (e.g., a piece) or a region of conductive material) located in a single level of memory device 200. The conductive material can include metal, doped polysilicon, or other conductive materials.

In the physical structure of memory device 200, a select gate (e.g., select gate 260 of select circuit 241a of sub-block SB0 of block BLK0) can include (can be formed from) a portion of the conductive material of a respective select line (e.g., select line 280₀ of sub-block SB0 of block BLK0), a portion of a channel material (e.g., polysilicon channel), and a portion of a dielectric material (e.g., similar to a gate oxide of a transistor [e.g., FET]) between the portion of the conductive material and the portion of the channel material.

FIG. 3 shows an example where memory device 200 includes one drain select gate (e.g., select gate 260) in each drain select circuit, and one source select gate (e.g., select gate 264) in each source select circuit coupled to a memory cell string. However, memory device 200 can include multiple drain select gates (e.g., multiple select gates 260 connected in series) in each drain select circuit, multiple source select gates (e.g., multiple select gates 264 connected in series) in each source select circuit, or both multiple drain select gates and multiple source select gates coupled to a memory cell string.

FIG. 4 shows a top view of a structure of a portion of memory device 200 of FIG. 2 and FIG. 3 including a region of memory array 201 including blocks BLK0 and BLK1, a region 454, and structures 451 between blocks, according to some embodiments described herein. For simplicity, some elements of memory device 200 (and other memory devices described herein) may be omitted from a particular figure of the drawings so as not to obscure the view or the description of the element (or elements) being described in that particular figure. Also, for simplicity, cross-sectional lines (e.g., hatch lines) are omitted from some or all the elements shown in the drawings described herein. Some elements of memory device 200 may be omitted from a particular figure of the drawings so as not to obscure the view or the description of the element (or elements) being described in that particular figure. Further, the dimensions (e.g., physical structures) of the elements of memory device 200 (and other memory devices) in the drawings described herein are not scaled. Moreover, the description of the same elements of memory device 200 described above with reference to FIG. 2 and FIG. 3 are also not repeated.

In FIG. 4, structures 451 can be formed to separate (physically separate) one block and another block of memory device 200. Two adjacent blocks (e.g., blocks BLK0 and BLK1) can be separated from each other by one of the structures 451. Each structure 451 can have a length in the Y-direction. Each structure 451 can include a dielectric material (e.g., silicon dioxide) or a combination of a dielectric material and additional material (e.g., a non-conductive material). Each structure 451 can include a slit (not labeled) and materials (not labeled) formed in (e.g., filled in) the slit. The slit can include (or can be part of) a trench between adjacent blocks (e.g., blocks BLK0 and BLK1. Structure 451 can be called a dielectric structure or a slit structure. The regions of memory device 200 at which structures 451 are located can be called slit regions.

As shown in FIG. 4, block BLK0 can include sub-blocks (e.g., four sub-blocks) SB0, SB1, SB2, and SB3 and select lines (e.g., four drain select lines) associated with signals SGD0₀, SGD1₀, SGD2₀, and SGD3₀, respectively. The select lines can include respective conductive regions (e.g., conductive materials) that are electrically separated from each other (in the X-direction) and can be located on the same level (with respect to the Z-direction). The select lines associated with signals SGD0₀, SGD1₀, SGD2₀, and SGD3₀ can be located over (with respect to the Z-direction) the control gates (under the select lines) of block BLK0. As shown in FIG. 4, each of the select lines (associated with signals SGD0₀, SGD1₀, SGD2₀, and SGD3₀) can have length in the Y-direction from memory array 201 to region 454. FIG. 4 shows an example where each block of memory device 200 can have four sub-blocks SB0, SB1, SB2, and SB3. However, the number of sub-blocks can be different from four.

Block BLK1 can have structure like block BLK0. As shown in FIG. 4, block BLK1 can include control gates associated with signals WL0₁, WL1₁, WL2₁, and WL3₁ (also shown in FIG. 3), select line (e.g., source select line) associated with signal SGS1 (also shown in FIG. 3), sub-blocks SB0, SB1, SB2, and SB3, select lines (e.g., drain select lines) SGD0₁, SGD1₁, SGD2₁, and SGD3₁.

FIG. 5 shows a side view (e.g., cross-section) of a structure of a portion of memory device 200 of FIG. 4 including tiers (tiers of materials) 525 that include respective memory cells and control gates associated with (e.g., to control) the memory cells, according to some embodiments described herein. FIG. 5 also partially shows other blocks (on the left and right sides of blocks BLK0 and BLK1) of memory device 200.

As shown in FIG. 5, memory device 200 can include a substrate 599, source 290 formed over substrate 599, and different levels 501 through 512 over substrate 599 in the Z-direction. Levels 501 through 512 are physical device levels of memory device 200 over substrate 599. Memory device 200 can include a dielectric material 581 formed over at least a portion of memory device 200. Memory cells 210, 211, 212, and 213 of the memory cell strings (e.g., memory cell string 231a in FIG. 3) of respective sub-blocks SB0, SB1, SB3, and SB3 of each of blocks BLK0 and BLK1 can be formed over substrate 599 and source 290 (e.g., formed vertically in Z-direction in respective levels among levels 501 through 512).

In FIG. 5, a data line 270 can be one of data lines 270₀ through 270_{N} in FIG. 4. Signal BL can be one of signals BL₀ through BL_{N} in FIG. 4.

In FIG. 5, the select lines (e.g., four drain select lines in the X-direction) indicated by signal SGD can correspond to respective select lines (e.g., drain select lines) of a respective block of blocks BLK0 and BLK1. For example, in sub-blocks SB0, SB1, SB2, and SB3 of block BLK0, the select lines (e.g., four drain select lines) indicated by signal SGD can correspond to respective select lines associated with signals SGD0₀, SGD1₀, SGD2₀, and SGD3₀ of block BLK0 shown in FIG. 4. In another example, in sub-blocks SB0, SB1, SB2, and SB3 of block BLK1, the select lines (e.g., four drain select lines in the X-direction) indicated by signal SGD can correspond to respective select lines associated with signals SGD0₁, SGD1₁, SGD2₁, and SGD3₁ of block BLK1 shown in FIG. 4.

As shown in FIG. 5, the select lines (e.g., four drain select lines) in the same block (e.g., block BLK0) can include respective conductive regions (e.g., four conductive regions) that are electrically separated from each other and can be located on the same level (e.g., level 512) in the Z-direction of memory device 200 and located over the control gates (in the Z-direction) of the respective block.

The select lines (e.g., source select lines) indicated by signal SGS (on level 501) can correspond to respective select lines of blocks BLK0 and BLK1. For example, in block BLK0, the select line indicated by signal SGS can correspond to the select line (e.g., source select line) associated with signals SGS0 of block BLK0 shown in FIG. 4. In another example, in block BLK1, the select line indicated by signal SGS can correspond to the select line (e.g., source select line) associated with signals SGS1 of block BLK1 shown in FIG. 4.

In FIG. 5, for simplicity, control gates (e.g., four control gates) of blocks BLK0 and BLK1 are indicated by the same signals WL0, WL1, WL2, and WL3. For example, in block BLK0, the control gates indicated by signals WL0, WL1, WL2, and WL3 can correspond to respective control gates associated with signals WL0₀, WL1₀, WL2₀, and WL3₀, respectively, of block BLK0 shown in FIG. 4. In another example, in block BLK1 in FIG. 5, the control gates indicated by signals WL0, WL1, WL2, and WL3 can correspond to respective control gates associated with signals WL0₁, WL1₁, WL2₁, and WL3₁, respectively, of block BLK1 shown in FIG. 4.

As shown in FIG. 5, memory device 200 can include dielectric materials (e.g., silicon dioxide) 521 located on levels 503, 505, 507, 509, and 511. Dielectric materials 521 in a respective block are interleaved with conductive materials 522. Conductive materials 522 can form respective control gates (associated with signals WL0, WL1, WL2, and WL3) in the respective block. As shown in FIG. 5, dielectric materials 521 can be located on respective levels among levels 501 through 512. Conductive materials 522 can be located on respective levels (e.g., levels 502, 504, 506, 508, 510, and 512) among levels 501 through 512 that are interleaved with the levels of dielectric materials 521. Examples of conductive materials 522 (which form the control gates) include a single conductive material (e.g., single metal [e.g., tungsten]) or a combination of different layers of conductive materials. For example, each of the control gates of blocks BLK0 and BLK1 can include (e.g., multi-layers of) aluminum oxide, titanium nitride, tungsten.

The levels of dielectric material 521 and the levels of conductive materials 522 can form tiers 525 of memory device 200. Each tier 525 can include a level of dielectric material 521 and a level of conductive material 522. For simplicity, only some of tiers 525 are labeled in FIG. 5. As shown in FIG. 5, tiers 525 can be located one over another and can include respective levels of memory cells 210, 211, 212, and 213, and control gates associated with the memory cells. FIG. 5 shows a few tiers (e.g., four tiers 525) of memory device 200 as an example. However, memory device 200 can include up to hundreds of tiers (or more than hundreds of tiers).

As shown in FIG. 5, memory device 200 can include pillars (memory cell pillars) 550 in blocks BL0 and BLK1. Each of the pillars 550 can be part of a respective memory cell string (e.g., memory cell string 231a). Each of the pillars 550 can have length extending outwardly (e.g., extending vertically in the direction of the Z-direction) from substrate 599 between substrate 599 and data line 270. As shown in FIG. 5, the Z-direction is also a direction at which the length of pillar 550 extends from one tier to another tier, which is also a direction from levels of dielectric materials 521 to levels of conductive materials 522.

As shown in FIG. 5, memory cells 210, 211, 212, and 213 of respective memory cell strings (e.g., memory cell string 231a) can be located in different levels (e.g., levels 504, 506, 508, and 510) in the Z-direction of memory device 200. The control gates (associated with signals WL0, WL1, WL2, and WL3) of each of blocks BLK0 and BLK1 can be located on the same levels (e.g., levels 504, 506, 508, and 510) at which memory cells 210, 211, 212, and 213 are located. Thus, memory cells 210, 211, 212, and 213 and the control gates of blocks BLK0 and BLK1 can be located (e.g., vertically located) along respective portions (e.g., portions on levels 504, 506, 508, and 510) of pillars 550 in the Z-direction.

Substrate 599 of memory device 200 can include monocrystalline (also referred to as single-crystal) semiconductor material. For example, substrate 599 can include monocrystalline silicon (also referred to as single-crystal silicon). The monocrystalline semiconductor material of substrate 599 can include impurities, such that substrate 599 can have a specific conductivity type (e.g., n-type or p-type).

As shown in FIG. 5, memory device 200 can include circuitry 595 located in (e.g., formed in) substrate 599. At least a portion of the circuitry can be located in a portion of substrate 599 that is under (e.g., directly under) memory cell strings of blocks BLK0 and BLK1. Circuitry 595 can include transistors (e.g., Tr1 and Tr2) that can be part of decoder circuits, driver circuits (e.g., word line drivers), buffers, sense amplifiers, charge pumps, and other circuitry of memory device 200.

In FIG. 5, source 290 can include a conductive material (or materials [e.g., different levels of different materials]) and can have a length extending in the X-direction. FIG. 5 shows an example where source 290 can be formed over a portion of substrate 599 (e.g., by depositing a conductive material over substrate 599). Alternatively, source 290 can be formed in or formed on a portion of substrate 599 (e.g., by doping a portion of substrate 599).

The select lines (associated with signals SGS and SGD) of blocks BLK0 and BLK1 can have the same material (or materials) as the control gates (associated with signals WL0, WL1, WL2, and WL3) of blocks BLK0 and BLK1. Alternatively, the select gates associated with signal SGS, SGD, or both have material (or materials) different from the material of the control gates.

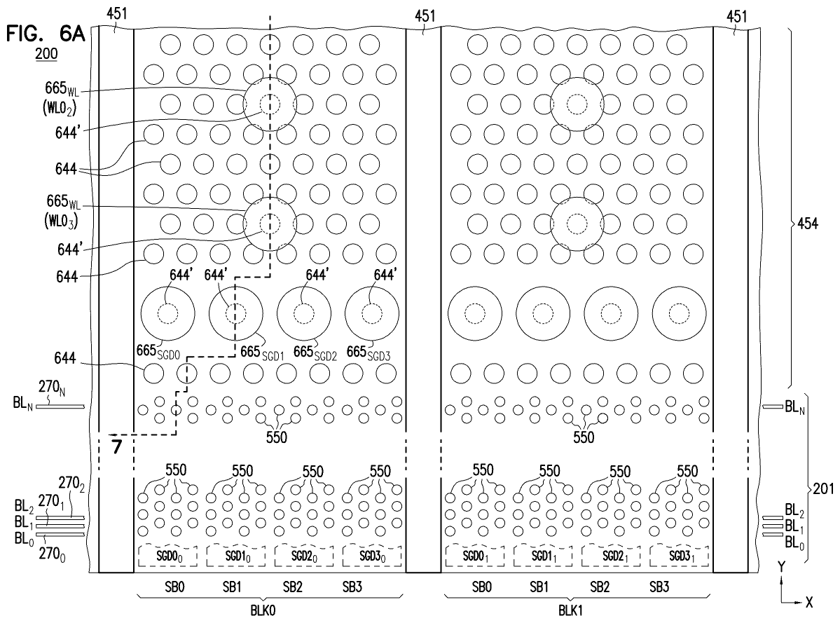

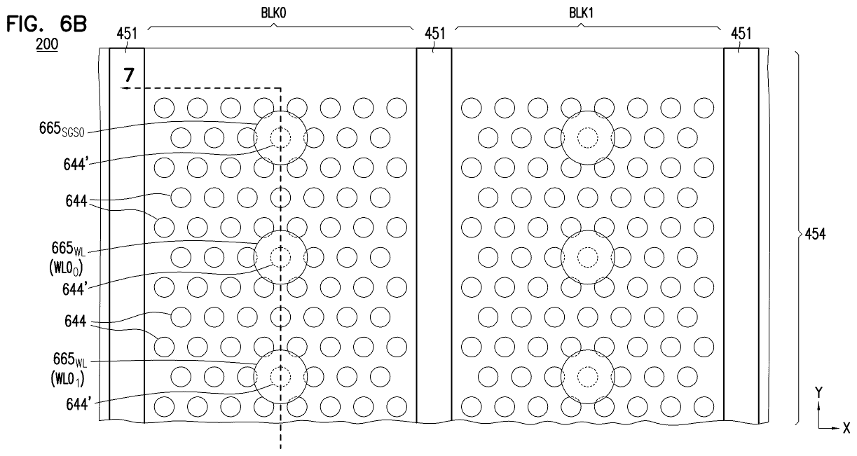

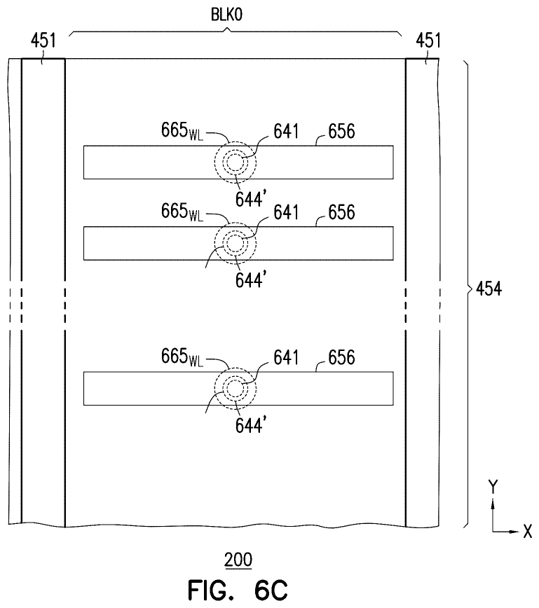

FIG. 6A and FIG. 6B show top views of a structure of memory device 200 of FIG. 4, according to some embodiments described herein. FIG. 6C shows a top view of additional elements of memory device 200 of FIG. 4, according to some embodiments described herein. FIG. 6A shows top views of pillars 550 located in the region included in memory array 201, which is adjacent region 454. As shown in FIG. 6A and FIG. 6B, in region 454, memory device 200 can include conductive contacts (e.g., word line contacts) 665_{WL}, conductive contacts (e.g., drain select line contacts) 665_{SGD0}, 665_{SGD1}, 665_{SGD2}, and 665_{SGD3}), and conductive (e.g., source select line contact) 665_{SGS0} (FIG. 6B) in region 454. Conductive contacts 665_{WL} can include metal (e.g., tungsten or other conductive materials). Although not shown in FIG. 6A and FIG. 6B for simplicity, memory device 200 (as shown in FIG. 6C) can include conductive lines 656 and conductive portions 641 coupled to respective conductive contacts (e.g., conductive contacts 665_{WL}, as shown in FIG. 6C) of memory device 200.

Conductive contacts 665_{WL} can contact (form electrical connection with) respective control gates (located under conductive contacts 665_{WL}, hidden from the top view of FIG. 6A and FIG. 6B). Conductive contacts 665_{WL} can be part of respective access lines (e.g., word lines) of memory device 200. Conductive contacts 665_{WL} allow signals (e.g., signals WL0₀, WL1₀, WL2₀, and WL3₀ in block BLK0 in FIG. 3) to be provided to respective control gates of block BLK0 through conductive contacts 665_{WL} in FIG. 6A and FIG. 6B. FIG. 7 (described in more detail below) show side views (e.g., cross-sections) of conductive contacts 665.

Similarly, for block BLK1 in FIG. 6A and FIG. 6B, conductive contacts (e.g., not labeled) can be formed at region 454 to allow signals (e.g., signals WL0₁, WL1₁, WL2₁, and WL3₁ in block BLK1 shown in FIG. 3) to be provided to respective control gates of block BLK1 through the conductive contacts at region 454. Region 454 can be called conductive contact region (e.g., word line conductive contact region) of memory device 200.

FIG. 6A and FIG. 6B also show top views of dielectric structures 644 and dielectric structures 644′. Each of dielectric structures 644 and 644′ can include a pillar (e.g., dielectric pillar 644′P) having lengths (shown in FIG. 7) extending the Z-direction. Dielectric structures 644 and dielectric structures 644′ can have the same dielectric material (e.g., silicon dioxide).

Dielectric structures 644 and 644′ can be formed to provide structural support to a portion (e.g., region 454) of memory device 200 (e.g., support during part of the processes of forming memory device 200). Dielectric structures 644 and 644′ can be called support structures at region 454 of memory device 200.

As shown from the top view (e.g., cross-section parallel to the X-Y plan) in FIG. 6A and FIG. 6B, conductive contacts 665_{WL}, 665_{SGD0}, 665_{SGD1}, 665_{SGD2}, and 665_{SGD3}, and 665 _{SGS0} can include portions surrounding respective portions of dielectric structures 644′.

In FIG. 6A, select lines associated with signals SGD0₀, SGD1₀, SGD2₀, and SGD3₀ in block BLK0 and signals SGD0₁, SGD1₁, SGD2₁, and SGD3₁ in block BLK1 are partially shown as dotted lines. Each of sub-blocks SB0, SB1, SB2, and SB3 can include multiple rows of pillars 550 associated with a respective select line (one of the select lines associated with signals SGD0₀, SGD1₀, SGD2₀, and SGD3₀). As shown in FIG. 6A, the multiple rows of pillars 550 can be located one after another in the X-direction (having lengths parallel to the Y-direction). FIG. 6A shows an example where each sub-block includes four rows of pillars 550. However, the number of rows in the sub-blocks can be less than four or greater than four.

In FIG. 6A, data lines 270₀ through 270_{N} are partially shown for simplicity. Data lines 270₀ through 270_{N} can extend across (in the X-direction) the blocks (e.g., blocks BL0 and BL1) and located over and in electrical contact with pillars 550. Connections (e.g., vertical connections in the Z-direction) between pillars 550 and data lines 270₀ through 270_{N} are not shown in FIG. 6. However, each pillar 550 in the same sub-block of a block can be coupled to a separate (e.g., unique) data line among data lines 270₀ through 270_{N}.

FIG. 6C shows a top view of a portion of memory device 200 including conductive lines 656 associated with block BLK0. For simplicity, only some of conductive lines 656 of memory device 200 are shown in FIG. 6C. Conductive lines 656 can be part of conductive paths (e.g., conductive paths 791 in FIG. 7) coupled to components (e.g., word line drivers) of circuitry 595 (FIG. 7) of memory device 200. As shown in FIG. 6C, memory device 200 can include conductive portions 641 that are located under and coupled to respective conductive contacts 665_{WL}. Conductive lines 656 of a block (e.g., BLK0) can be formed (e.g., patterned) such that they can be electrically separated from other conductive lines 656 (not shown) of another block (e.g., block BLK1).

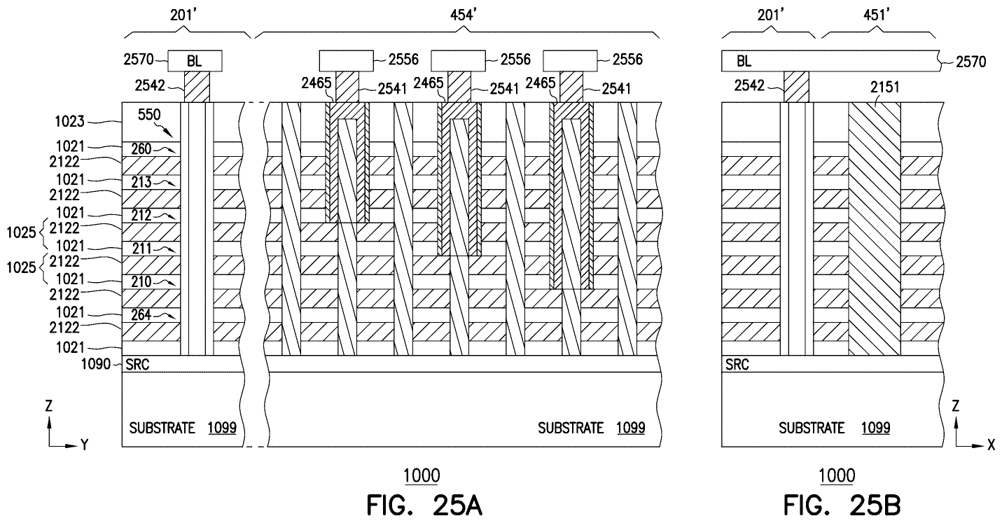

Conductive portions 641 can be similar to (or the same as) conductive portions 2541 (FIG. 25A). In FIG. 6C, a conduct portion 641 and a corresponding conductive contact 665 (that are coupled to the same conductive line 656) can be called a conductive contact structure (e.g., a word line contact structure) associated with a respective conductive line 656.

A side view (e.g., cross-section) along line 7-7 in FIG. 6A and FIG. 6B of block BLK0 is shown in FIG. 7.

FIG. 7 shows a side view of a portion of memory device 200 including conductive contacts 665_{WL}, 665_{SGD0}, and 665_{SGS0} in region 454, and pillar 550 in memory array 201, according to some embodiments described herein. Levels 501 through 512 and tiers 525 of memory device 200 in FIG. 7 are the same as those shown in FIG. 5. As shown in FIG. 7, pillar 550 can be located in the portion of memory device 200 that includes memory array 201, which is also shown in top view in FIG. 4 and FIG. 6. Pillar 550 can extend through conductive materials 522 (which form the control gates and the select lines) and dielectric materials 521 in the portions that include memory array 201.

As shown in FIG. 7, memory device 200 can include a structure 730 and a dielectric material 705 that can be part of pillar 550. Structure 730 and a dielectric material 705 can extend continuously (in the Z-direction) along the length of the respective pillar 550. Dielectric material 705 can include silicon dioxide. Structure 730 can be electrically coupled to source 290 and a respective data line (e.g., one of data line 270₀ through 270_{N} in FIG. 3 and FIG. 6). Structure 730 of a respective pillar 550 in a block is adjacent portions of respective control gates of that block. For example, structure 730 of pillar 550 in block BLK0 is adjacent to the control gates associated with signals WL0₀, WL1₀, WL2₀, and WL3₀, respectively.

Structure 730 can include a conductive structure that can be part of a conductive path (e.g., pillar channel structure) to conduct current between a respective data line (e.g., one of data line 270₀ through 270_{N} in FIG. 3 and FIG. 6A) coupled to structure 730 and source 290. Structure 730 can also include a material (or materials) that can form a charge storage element (e.g., a memory element) of a respective memory cell (among memory cells 210, 211, 212, and 213) located along a portion of pillar 550. As an example, structure 730 can be part of an ONOS (SiO₂, Si₃N₄, SiO₂, Si) where Si₃N₄ material can form a charge storage element of a respective memory cell, and Si material can be part of the pillar channel structure of pillar 550. In another example, structure 730 include can be part of a SONOS (Si, SiO₂, Si₃N₄, SiO₂, Si) structure, a TANOS (TaN, Al₂O₃, Si₃N₄, SiO₂, Si) structure, a MANOS (metal, Al₂O₃, Si₃N₄, SiO₂, Si) structure, or other structures. Alternatively, structure 730 can include a floating gate structure (e.g., polysilicon structure) where the floating gate structure can form a charge storage element of a respective memory (among memory cells 210, 211, 212, and 213) located along a portion of pillar 550.

As shown in FIG. 7, the control gates associated with signals WL0₀, WL1₀, WL2₀, and WL3₀, and the select lines associated with signals (e.g., drain select signal and source select signal) SGD0₀ and SGS0 can be structured (e.g., patterned), such that they may have the same length in the Y-direction. For example, the control gates (formed from respective materials 522) associated with signals WL1₀, WL2₀, and WL3₀ can have the same length (in the Y-direction) measuring between pillar 550 and edges 522E of respective the control gates. Edges 522E are part of respective conductive materials 522. As shown in FIG. 7, the control gates associated with signals WL0₀, WL1₀, WL2₀, and WL3₀ can have the same length, such that edges 522E can be aligned (e.g., vertically aligned) with each other at a reference location (e.g., reference point) 722 in the X-direction).

As shown in FIG. 7, dielectric structures 644 can include respective pillars (dielectric pillars) 644P that can include respective lengths extending in the Z-direction. Similarly, dielectric structures 644′ can include respective pillars (dielectric pillars) 644′P that can include respective lengths extending in the Z-direction. As shown in FIG. 7, the length of dielectric structures 644 (e.g., from source 290 to a surface of material 581) can be greater than the length of dielectric structures 644′. Pillars (dielectric pillars) 644P and 644′P can be called support pillars in region 454 of memory device 200.

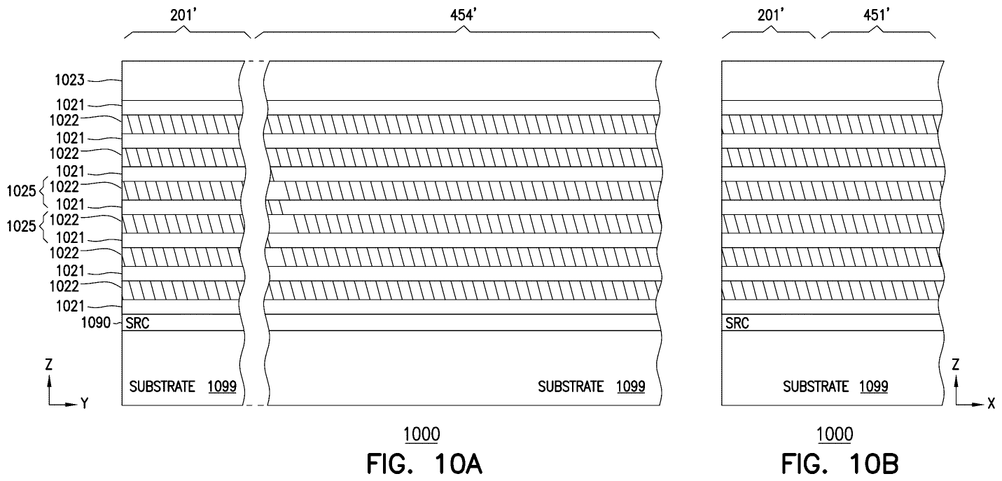

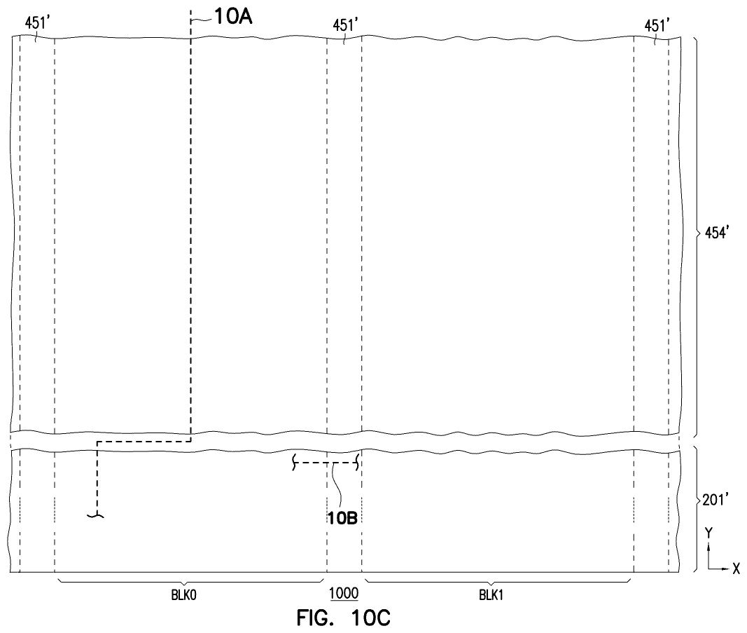

During the processes of forming memory device 200 that can be similar to the processes of forming memory device 1000 of FIG. 10A through FIG. 25B, collapse (e.g., in the Z-direction) of some structures (e.g., collapse in part of the levels of conductive materials 522 in region 454) of memory device 200 may occur. Dielectric structures 644 and 644′ can be formed in memory device 200 to prevent such collapse. In an alternative structure of memory device 200, dielectric structures 644′ can be removed (not to be included in) from memory device 200. However, including (e.g., keeping) dielectric structures 644′ in memory device 200 (as shown in FIG. 7) can further maintain support for the structure (e.g., at region 454) of memory device 200. Such support associated with dielectric structures 644′ lead to improvement in at least one of yield, cost, performance, and reliability of memory device 200 and other memory devices (e.g., memory devices 900, 1000, and 2600) described herein.

As shown in FIG. 7, dielectric structures 644 and 644′ can extend through (e.g., go through) and contact respective portions of dielectric materials 521 and conductive materials 522. Dielectric structures 644 and 644′ can contact (e.g., lands on) on the material of source 290 Dielectric structures 644 and 644′ are electrically separated from conductive materials 522. Each dielectric structures 644 and 644′ can contact dielectric materials 521 and conductive materials 522. Dielectric structures 644 and 644′ are electrically separated from conductive materials 522. As shown in FIG. 7, dielectric structure 644′ can be between (in the Y-direction in FIG. 7) pillar (memory cell pillar) 550 and edges 522E of respective levels of conductive materials 522.

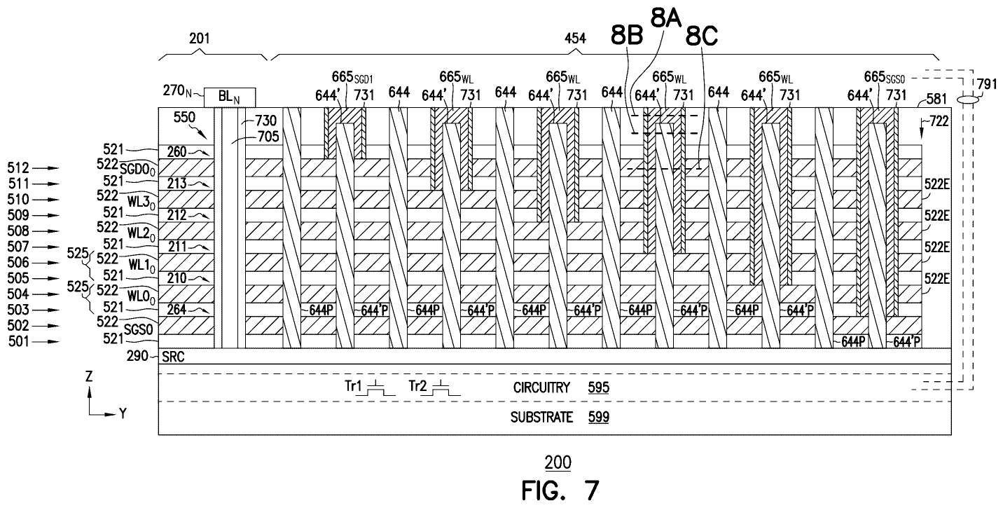

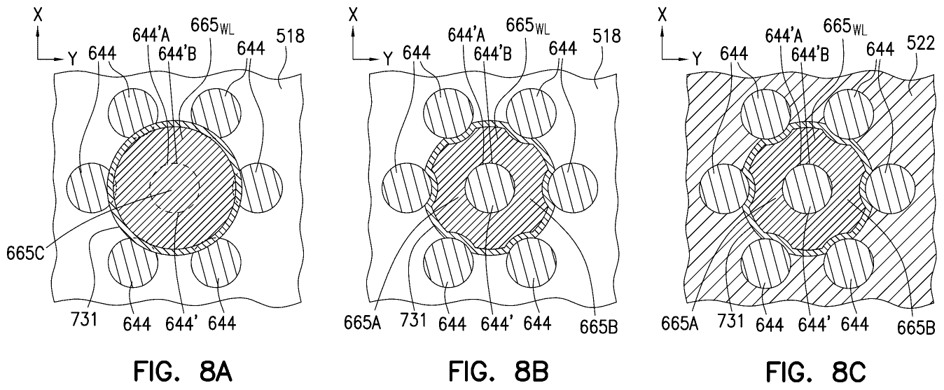

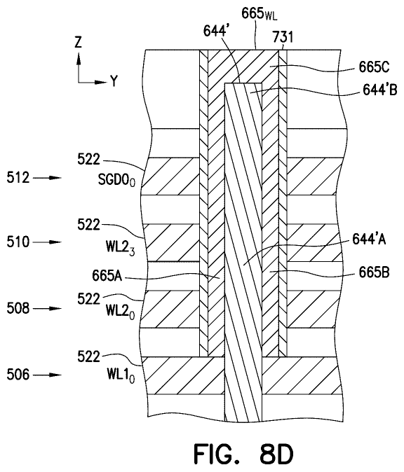

As shown in FIG. 7, memory device 200 can include conductive paths (e.g., conductive routings) 791 to form circuit paths between circuitry 595 and other elements of memory device 200. For example, conductive lines 656 (FIG. 6C) associated with the control gates (e.g., control gates associated with signals WL0₀, WL1₀, WL2₀, and WL3₀ in FIG. 7) of memory device 200 can be part of (or can be couple to) conductive paths 791. This allows the control gates to couple to circuitry 595 through conductive lines conductive lines 656 (FIG. 6C) and conductive paths 791 (FIG. 7). Different views (e.g., cross-sections) along lines 8A, 8B, and 8C in FIG. 7 are shown in FIG. 8A, FIG. 8B, and FIG. 8C, respectively.

FIG. 8A, FIG. 8B, and FIG. 8C show top views (e.g., cross-sections) along lines 8A, 8B, and 8C in FIG. 7, according to some embodiments described herein. FIG. 8D shows an enlarged portion of memory device 200 at conductive contact 665_{WL} associated with the control gate associated with signal WL2₀ of FIG. 7.

As shown in FIG. 8A through FIG. 8D, dielectric structure 644′ can include a portion 644′A and a portion 644′B. Portion 644′B can be called an end portion of dielectric structure 644′. As shown in FIG. 8D, portion (e.g., end portion) 644′A of dielectric structure 644 can extend (extends in the Z-direction from level 506 to level 512) passed at least one level (e.g., at least one of levels 506, 508, 510, and 512) among the levels of conductive materials 522.

As shown in FIG. 8D, conductive contact 665_{WL} can include a portion 665A, a portion 665B, and a portion 665C. As shown in FIG. 8A and FIG. 8D, portion 665C of conductive contact 665WL can be located directly over dielectric structure 644′ (e.g., directly over portion 644′B of dielectric structure 644′). At least a portion (e.g., portion 665C) of conductive contact 665_{WL} can be aligned (along the Z-direction) with dielectric structure 644′. For example, portion 665C of conductive contact 655 _{WL} can be aligned with dielectric structure 644′, such that portion 665C can overlap (in the viewing from top view of FIG. 8A or side view in FIG. 8D) dielectric structure 644′. As shown in FIG. 8B and FIG. 8C, conductive contact 665_{WL} can surround a portion (e.g., portion 665A, portion 665B, or both) of dielectric structure 644′.

As shown in FIG. 8D, portion 644A of dielectric structure 644′ can be between portion 665A and portion 665B of conductive contact 665_{WL}. Portion 644A of dielectric structure 644′ can also contact portion 665A and portion 665B of conductive contact 665 _{WL}. As shown in FIG. 8D, part of dielectric structure 644′ (e.g., portions 644′A and 644′B of dielectric structure 644′) can protrude into (e.g., can be embedded in) part of conductive contact 665_{WL}.

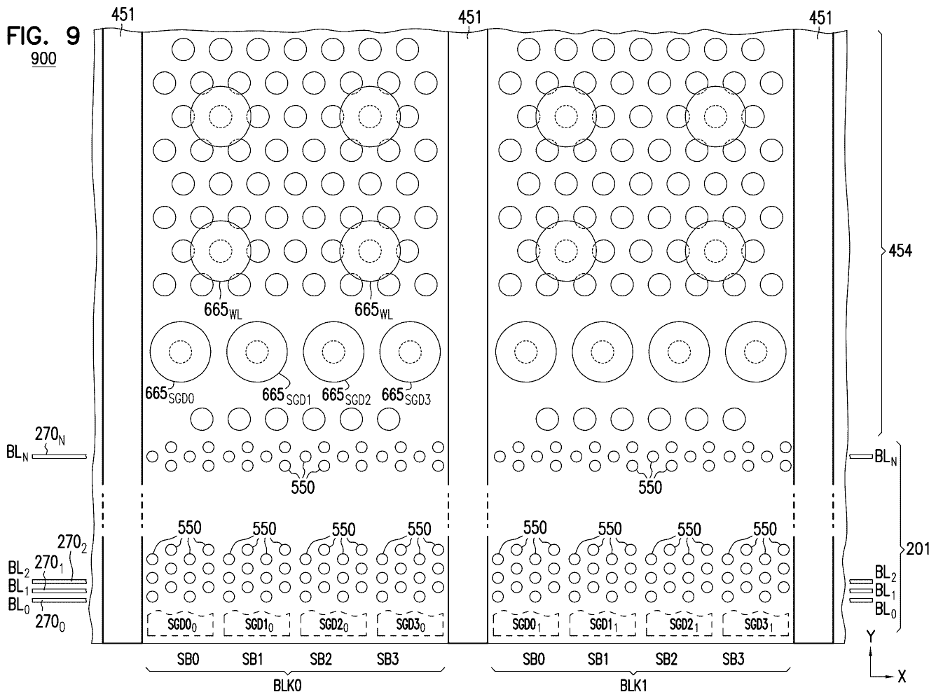

FIG. 9 shows a memory device 900 that can be variation of memory device 200, according to some embodiments described herein. As show in FIG. 9 and FIG. 6A, memory device 900 can include elements that are similar to or the same as the elements of memory device 200 multiple 665_{WL}. For simplicity, descriptions of similar or the same elements between memory devices 200 and 900 are not repeated. In comparison with memory device 200 (FIG. 6A), memory device 900 (FIG. 9) can include a higher number of conductive contacts (e.g., conductive contacts 665_{WL}) and associated dielectric structures 644′ in region 454. For example, as shown in FIG. 9, memory device 900 can include multiple (e.g., two are shown as an example) conductive contacts 665_{WL} and associated dielectric structures 644′ in region 454 that may be formed (e.g., formed in respective rows) in the X-direction. In the example of FIG. 9, multiple conductive contacts 665_{WL} (e.g., conductive contacts in the same row in the X-direction) can be coupled to (can contact) the same control gate. Alternatively, multiple conductive contacts (e.g., conductive contacts in the same row in the X-direction) can be coupled to (can contact) different control gates.

The above description with reference to FIG. 2 through FIG. 9 describes the structure of memory devices 200 and 900. Some or all of the structure of memory devices 200 and 900 can be formed using processes associated with the processes described below with reference to FIG. 10A through FIG. 31.

FIG. 10A through FIG. 25B show different views of elements during processes of forming a memory device 1000, according to some embodiments described herein. FIG. 10A shows a side view (e.g., cross-section) in the Y-direction of a portion of memory device 1000. FIG. 10B shows a side view (e.g., cross-section) in the X-direction (e.g., perpendicular to the Y-direction) of a portion of memory device 1000. FIG. 10C shows the locations of the side views of memory device 1000 of FIG. 10A and FIG. 10C that are taken along lines 10A and 10B, respectively, of FIG. 10C. Line 10A in FIG. 10C is similar to part of line 7 of FIG. 6A and FIG. 6B.

In FIG. 10C, the region included in memory array 201′ is similar to the region included in memory array 201 of memory device 200 in FIG. 6A In FIG. 10C, regions (e.g., slit regions) 451′ can be similar to the regions of structures 451 (FIG. 4) of memory device 200.

FIG. 10A and FIG. 10B, the process of forming memory device 1000 can include forming a material 1090 over substrate 1099. Material 1090 can form part of a source (e.g., associated with signal SRC) that is similar to source 290 of FIG. 7. Substrate 1099 is similar to (e.g., can correspond to) substrate 599 (FIG. 7) of memory device 200.

The processes associated with FIG. 10A and FIG. 10B include forming dielectric materials (levels of dielectric materials) 1021 and dielectric materials (levels of dielectric materials) 1022 over substrate 1099 (e.g., over material 1090). Dielectric materials 1021 can include silicon dioxide. Dielectric materials 1022 can include silicon nitride. Dielectric materials 1021 and 1022 can be sequentially formed one material after another over substrate 1099 in an interleaved fashion, such that dielectric materials 1021 can be interleaved with dielectric materials 1022. A dielectric material 1023 may also be formed over the interleaved materials 1021 and 1022.

As shown in FIG. 10A, dielectric materials 1021 and 1022 can form tiers (tiers of materials) 1025. Tiers 1025 are located one over another in the Z-direction. Each tier 1025 can include a respective level of dielectric material 1021 and a respective level of dielectric material 1022.

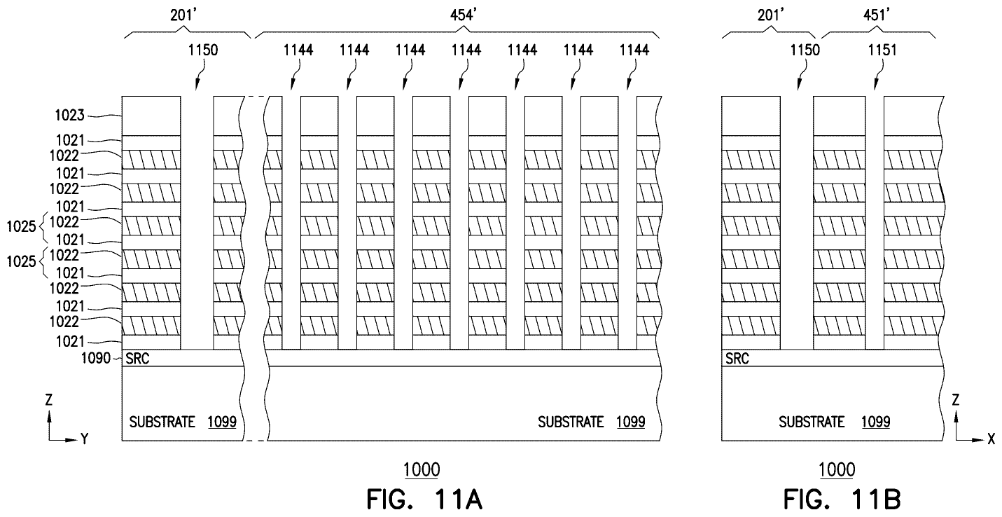

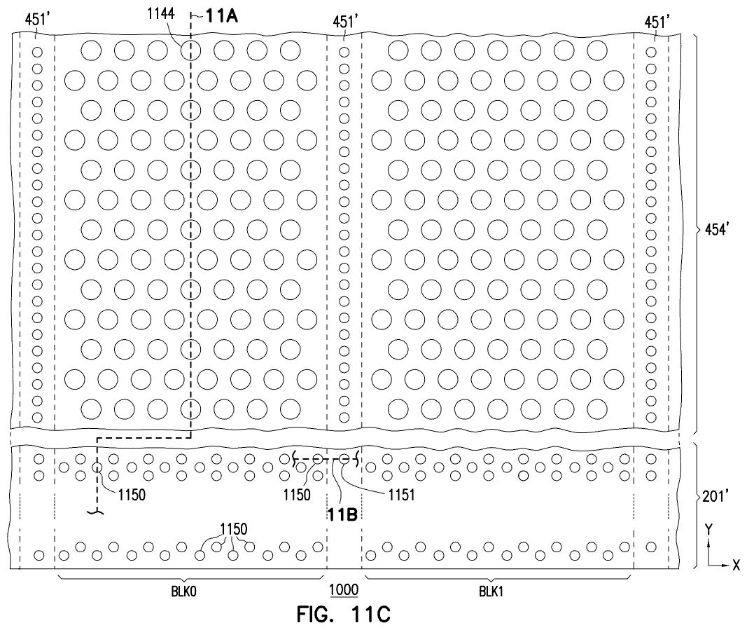

FIG. 11A, FIG. 11B, and FIG. 11C show memory device 1000 after openings (e.g., holes) 1150, 1144, and 1151 are formed. Forming openings 1150, 1144, and 1151 can include removing a portion of dielectric material 1023 and dielectric materials 1021 and 1022 at the locations of contact openings 1150, 1144, and 1151.

For simplicity, a top view (e.g., like FIG. 10C and FIG. 11C) of memory device 1000 are omitted from subsequent processes of forming a memory device 1000 associated with FIG. 12A through FIG. 25B.

FIG. 12A and FIG. 12B show memory device 1000 after a material (or materials) 1224 is formed (e.g., filled) in openings 1150, 1144, and 1151. In subsequent processes of forming memory device 1000, material 1224 can be removed (e.g., at different times) from openings 1150, 1144, and 1151. Thus, material 1224 can be called a sacrificial material. An example of material 1224 can include carbon or other materials. Forming material 1224 can include forming a material (e.g., carbon) in openings 1150, 1144, and 1151. A chemical mechanical polishing (CMP) process can be performed after material 1224.

FIG. 13A and FIG. 13B show memory device 1000 after pillars (memory cell pillars) 550′, including structure 730′, and a dielectric material 705′ are formed. Pillars 550′, structure 730′, and dielectric material 705′ are similar to (e.g., can correspond to) Pillars 550, structure 730, and dielectric material 705 of memory device 200 of FIG. 7. Forming pillars 550′ can include removing (exhuming) material 1224 from openings 1150 in the region of memory cell array 201′. Then, forming pillars 550′ (which include structure 730′ and dielectric material 705′) at the locations of openings 1150 (labeled in FIG. 11). Material 1224 in openings 1144 (in region 454′) and opening 1151 (in region 451′) can remain (not removed) during the processes associated with FIG. 13A and FIG. 13B. Similar to pillar 550 (FIG. 7), each pillar 550′ of FIG. 13A and FIG. 13B can include select gates 260 and 264 and memory cells (e.g., like memory cells 210, 211 212, and 213 in FIG. 7) of a respective memory cell string.

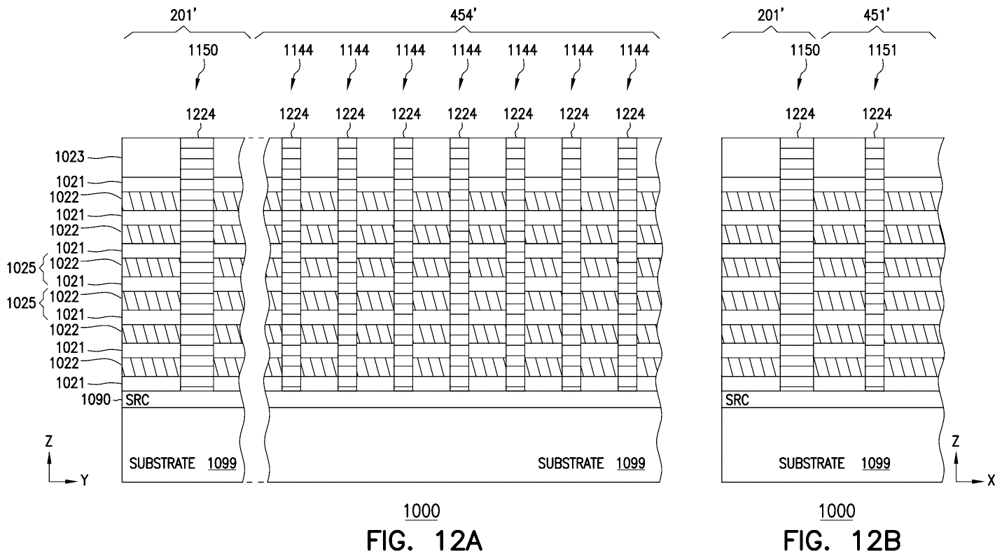

FIG. 14A and FIG. 14B show memory device 1000 after material 1224 (labeled in FIG. 12) is removed (e.g., exhumed) from openings 1144. Material 1224 at region 451′ in openings 1151 can remain (not removed) during the processes associated with FIG. 14A and FIG. 14B.

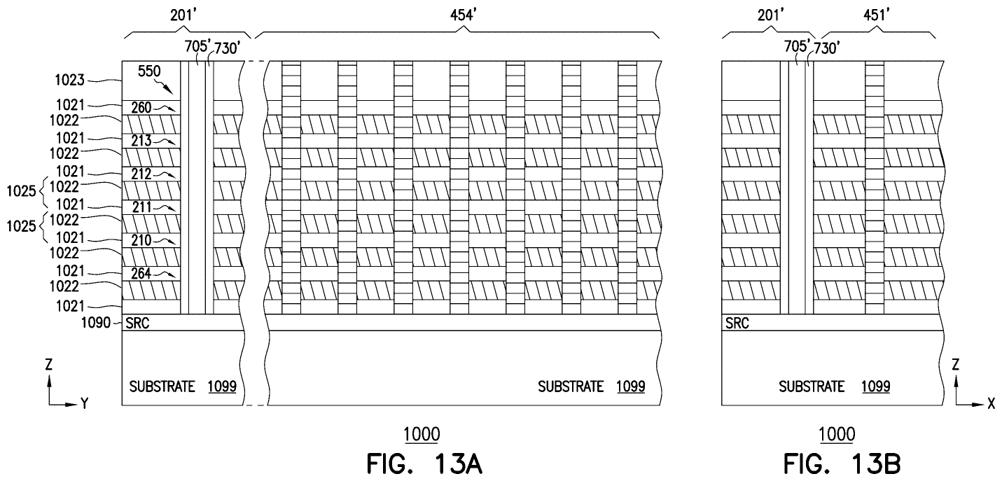

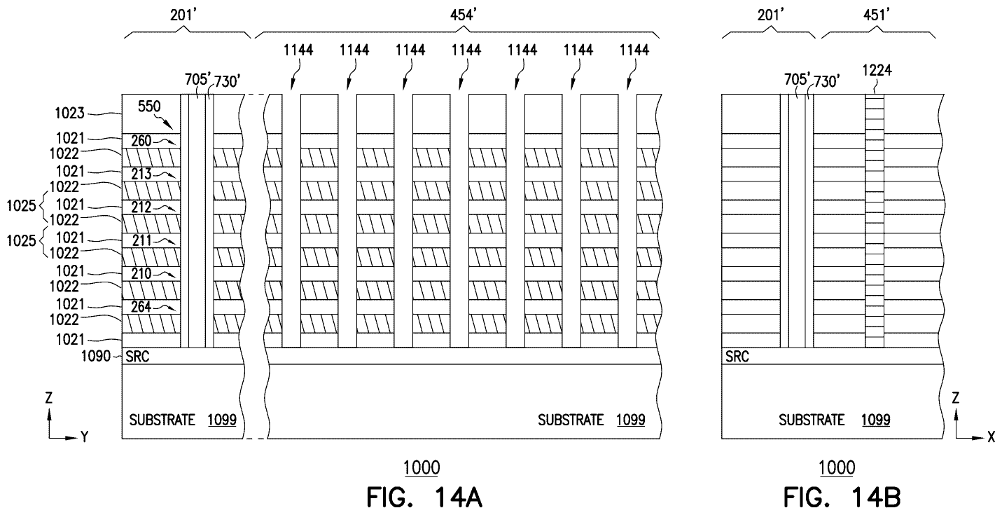

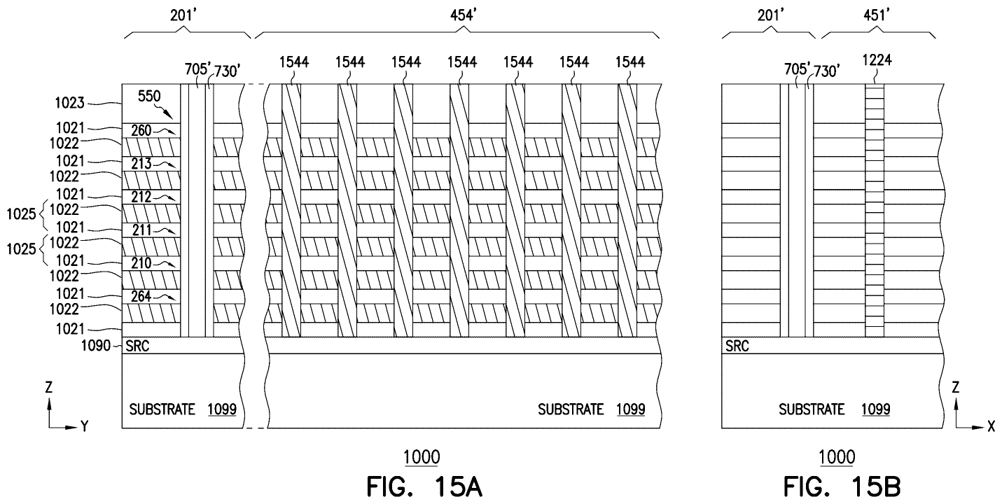

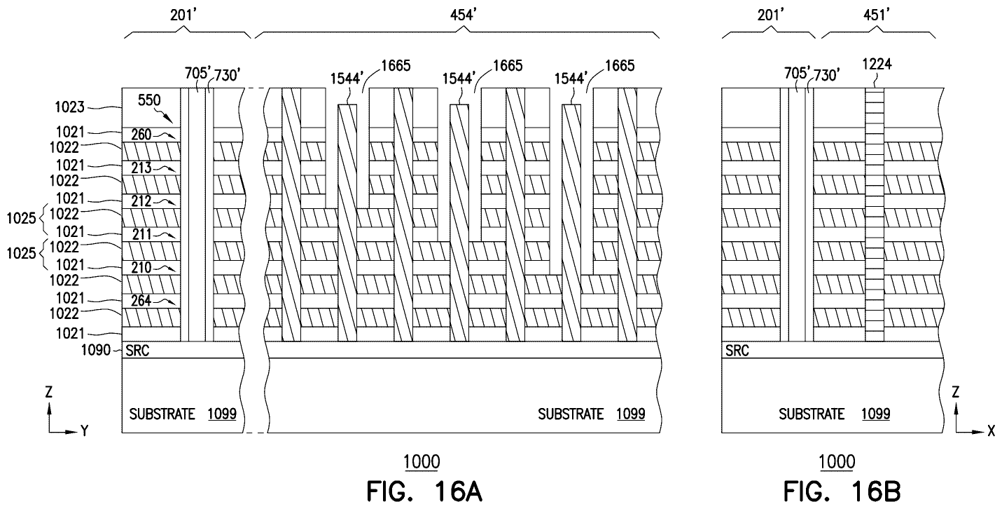

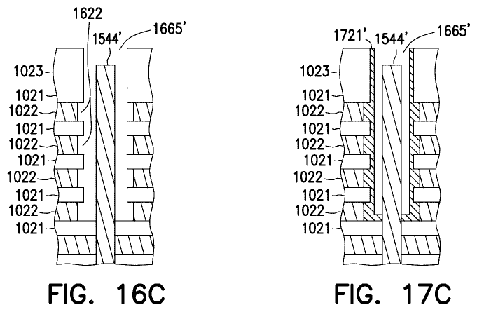

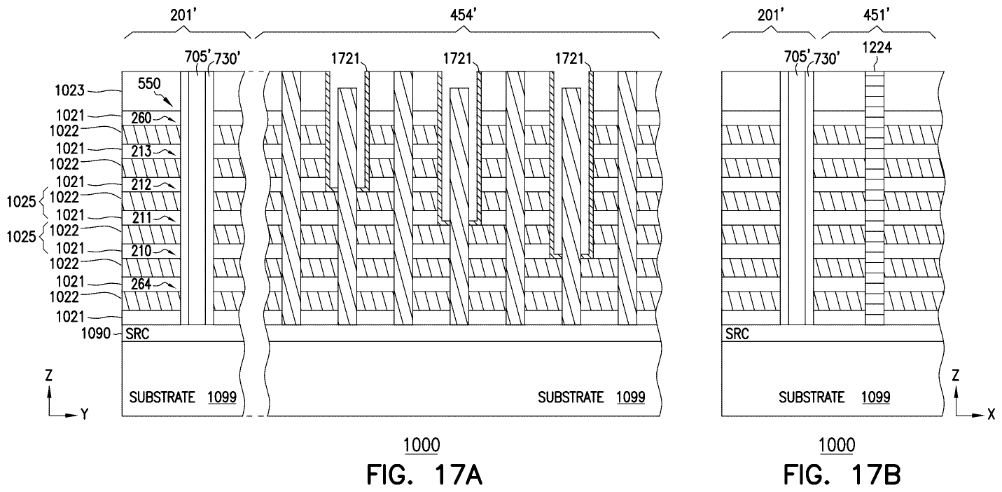

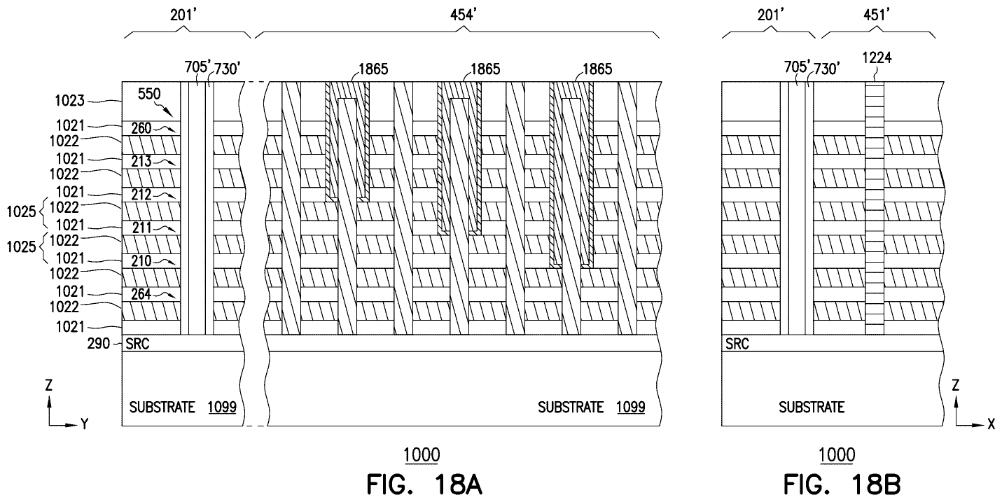

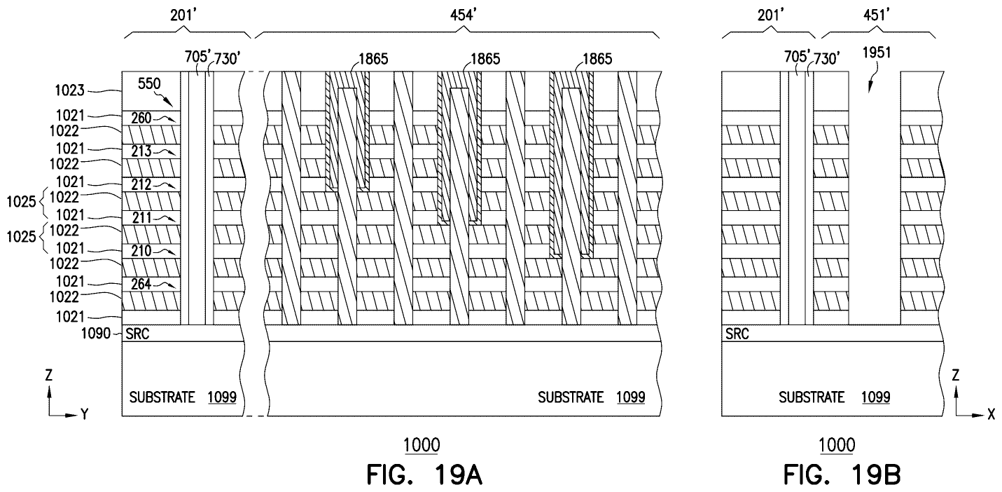

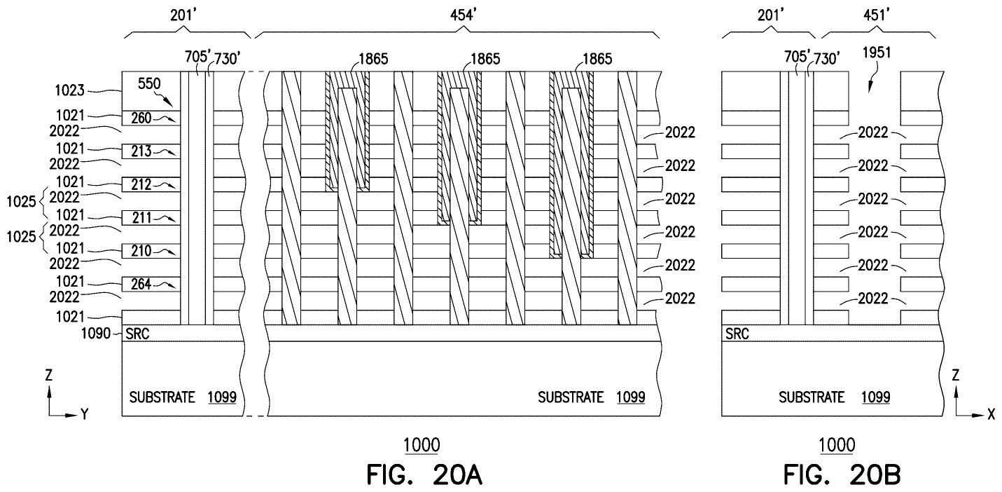

FIG. 15A and FIG. 15B show memory device 1000 after dielectric structures 1544 are formed in openings 1144 (labeled in FIG. 14A). Forming dielectric structures 1544 can include forming (e.g., filling) a dielectric material in openings 1144. An example the dielectric material of dielectric structures 1544 can include silicon dioxide. Alternatively, the dielectric material of dielectric structures 1544 can include a material (e.g., different from silicon dioxide) that can be less susceptible to be removed (e.g., etched slower than dielectric materials 1021 and 1022) during processes associated with FIG. 16A at which a portion of dielectric materials 1021 and 1022 is removed (to form contact openings 1665). This allows the dielectric material (or a majority of the dielectric material) of dielectric structures 1544 to remain in memory device 1000 during the processes associated with FIG. 16A at which a portion of dielectric materials 1021 and 1022 is removed (to form contact openings 1665 (FIG. 16A). Further, the dielectric material of dielectric structures 1544 (FIG. 15) can include a material (e.g., different from silicon dioxide) that can remain in memory device 1000 during the processes associated with FIG. 20A at which dielectric material 1022 are removed (to be replaced with a conductive material that forms control gates associated with memory cells 210, 211, 212, and 213).

FIG. 16A and FIG. 16B show memory device 1000 after contact openings 1665 and dielectric structure 1544′ are formed. Forming contact openings 1665 can include removing a portion of dielectric materials 1021 and 1022 at the locations of contact openings 1665. Dielectric structure 1544′ can be similar to dielectric structure 644′ of memory device 200 of FIG. 7.

In FIG. 16A, dielectric structure 1544′ in contact openings 1665 are remaining portions of dielectric structure 1544 (FIG. 15A). As shown in FIG. 16A, the length (in the Z-direction) of dielectric structure 1544′ can be less than the length of dielectric structure 1544 because a relatively small portion (e.g., top portion) of dielectric structure 1544 (FIG. 15A) may be removed during the process of forming contact openings 1665. However, in an alternative process of forming memory device 1000, the structure (e.g., the length) of dielectric structure 1544′ may be similar to (or the same as) the structure of the dielectric structure 1544.

As shown in FIG. 16A, at least a portion of each dielectric structure 1544′ is exposed at a respective contact opening 1665. In subsequent processes, conductive contacts (like conductive contacts 665_{WL} in FIG. 7) are formed in contact openings 1665. As shown in FIG. 16A, contact openings 1665 can include different depths in the Z-direction corresponding to the different levels of dielectric materials 1022.

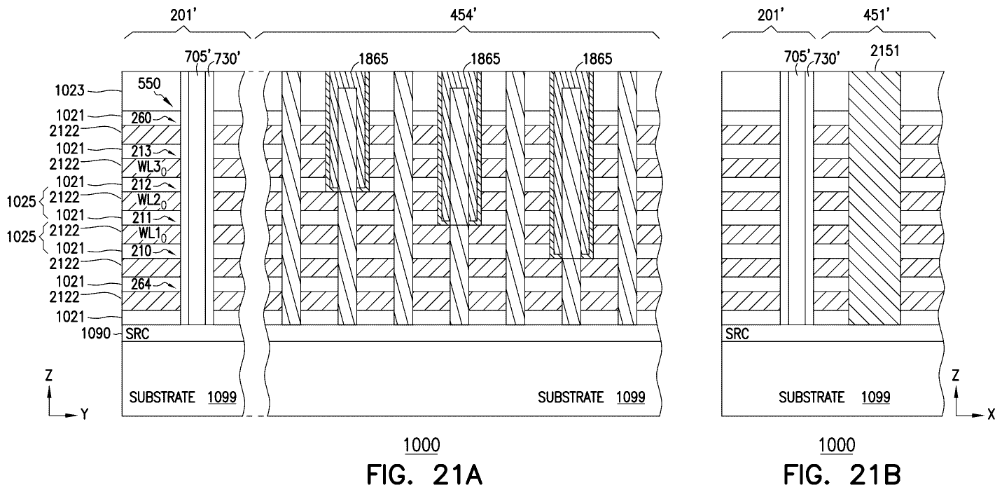

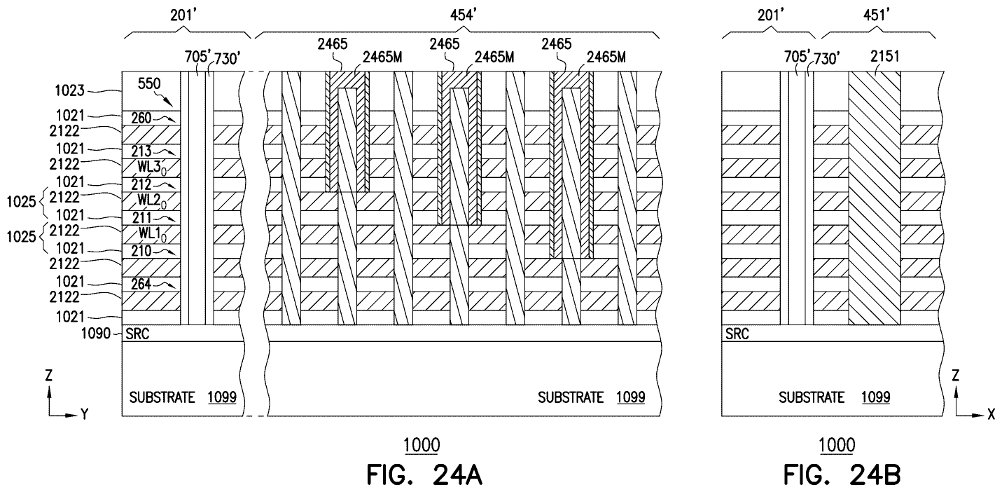

FIG. 16C shows an alternative process that includes forming contact openings 1665′ (like the process associated with FIG. 16A) with an additional processing of further removing a respective portion of materials (e.g., silicon nitride) at locations 1622. As shown in FIG. 16C contact openings 1665′ can have a different structure (e.g., different shape of the side walls) relative to the structure of contact openings 1665 in FIG. 16A. In FIG. 16C, removing a respective portion of materials (e.g., silicon nitride) at locations 1622 can increase the effective width of dielectric isolation from one conductive contact to another conductive contact (e.g., conductive contacts 2465 (FIG. 24) contacting respective levels of conductive materials 2122 (FIG. 21A) that form part of the control gates (associated with signals WL1₀, WL2₀, and WL3₀) of memory device 1000.

FIG. 17A and FIG. 17B show memory device 1000 after liners (dielectric liners) 1721 and dielectric structure 1544′ are formed in contact openings 1665. Forming liners 1721 can including forming a dielectric material (e.g., silicon dioxide) in contact openings 1665. The dielectric material that covers side walls and bottom of contact openings 1665 can be relatively thin (as shown in FIG. 17A).

FIG. 17C shows an alternative process that includes forming liners 1721′ (like the process associated with FIG. 17A) associated with contact openings 1665′ in FIG. 16C. As shown in FIG. 17C liners 1721′ can have a different structure (e.g., different shape) relative to the structure of liners 1721. Forming liners 1721′ can further the (e.g., increase) reliability, density and capability associated with conductive contacts of memory device 1000.

FIG. 18A and FIG. 18B show memory device 1000 after a material (e.g., a dielectric material) 1865 is formed (e.g., filled) in contact openings 1165 (labeled in FIG. 16). In subsequent processes of forming memory device 1000, material 1865 can be removed from openings 1665. Thus, material 1865 can be called a sacrificial material. A CMP process can be performed after material 1865 is formed.

FIG. 19A and FIG. 19B show memory device 1000 after a slit (e.g., a trench) 1951 is formed at region 451′. Forming a slit 1951 can include removing material 1224, a portion of dielectric material 1023, and a portion of dielectric materials 1021 and 1022 at the location of slit 1951.

FIG. 20A and FIG. 20B show memory device 1000 after dielectric materials 1022 (FIG. 19A) are removed (e.g., exhumed) from locations 2022. Locations 2022 in FIG. 20 are voids (empty spaces) that were occupied by dielectric materials 1022. In subsequent processes, conductive materials can be formed in locations 2022 to form respective control gates of memory device 1000.

FIG. 21A and FIG. 21B show memory device 1000 after conductive materials (levels of conductive materials) 2122 are formed in locations 2022 (FIG. 20). Conductive materials 2122 can form part of the control gates and select lines of memory device 1000 that can be similar to the control gates associated with signals associated with signals WL0₀, WL1₀, WL2₀, and WL3₀ (FIG. 7) of memory device 200 (FIG. 7) and the select line associated with signal SGD0₀ and SGD₀ (FIG. 7) of memory device 200. FIG. 21 shows an example where some of the levels of conductive materials 2122 can form the control gates (e.g., the control gates similar to control gates associated with signals WL1₀, WL2₀, and WL3₀ of memory device 200 of FIG. 7) of memory device 1000. Thus, forming conductive materials 2122 includes forming the control gates and select lines of memory device 1000.

In FIG. 21A and FIG. 21B, forming conductive materials 2122 can include forming (e.g., filling) a conductive material (or a combination of conductive materials) 2122 in locations 2022 (FIG. 20). As described above, locations 2022 are locations of dielectric materials 1022 (FIG. 19) that were removed in FIG. 20. Thus, in FIG. 21, forming the control gates (e.g., the control gates associated with signals WL0₀, WL1₀, and WL3₀) and the select lines of memory device 1000 can include replacing the levels of dielectric materials 1022 (FIG. 19) with respective levels of conductive materials 2122 (FIG. 21A). Conductive materials 2122 can include a similar material or the same material as conductive materials 522 (FIG. 7) of memory device 200. Thus, conductive materials 2122 can include a single conductive material (e.g., single metal (e.g., tungsten)) or a combination of different layers of conductive materials. For example, conductive material 2122 can include (e.g., multi-layers of) aluminum oxide, titanium nitride, and tungsten, or other conductive materials.

As shown in FIG. 21B, a structure 2151 is formed in slit 1951 (labeled in FIG. 20). Structure 2151 can be similar to structure 451 (FIG. 4) of memory device 200. Forming structure 2151 can include forming (e.g., filling) a material (or materials) in slit 1951. Example materials of structure 451 include a dielectric material (e.g., silicon oxide) or other materials.

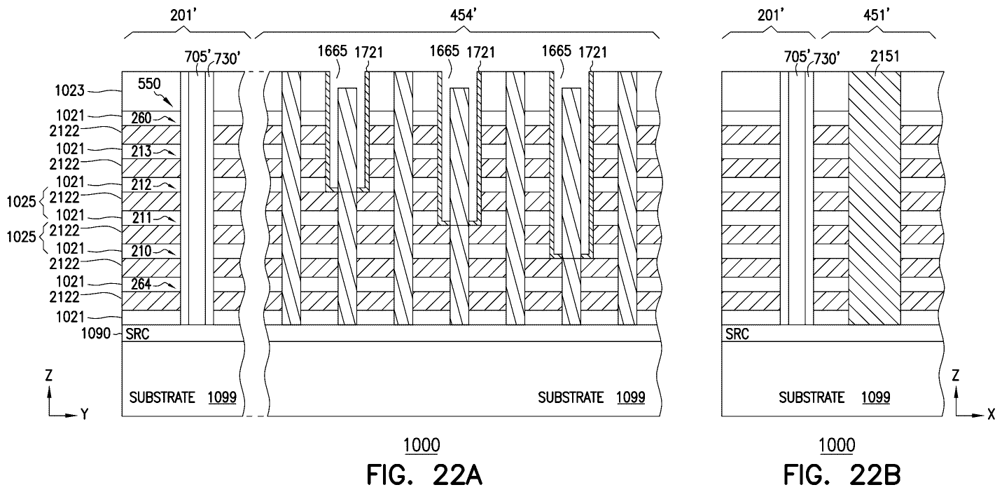

FIG. 22A and FIG. 22B show memory device 1000 after material 1865 (labeled in FIG. 21) is removed (e.g., exhumed) from contact openings 1665.

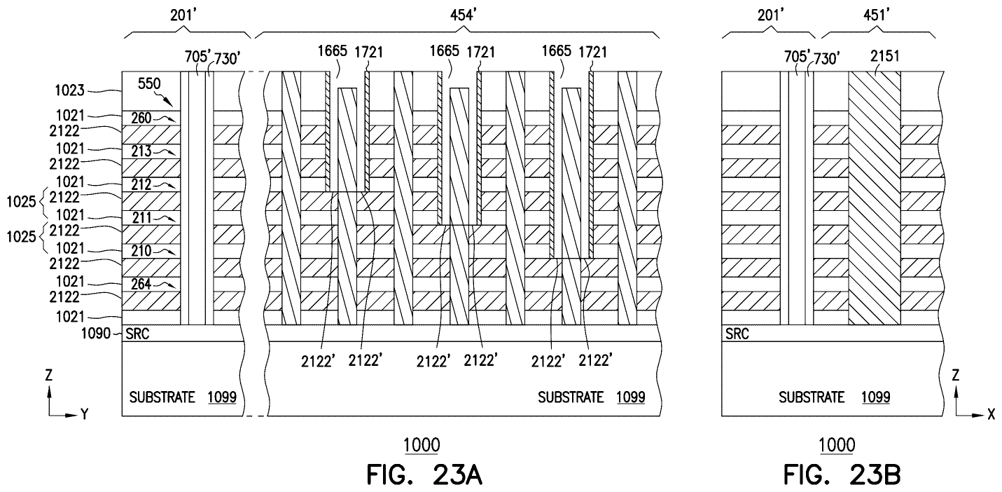

FIG. 23A and FIG. 23B show memory device 1000 after a portion (e.g., bottom portion) of liners 1721 is removed (e.g., punch through). As shown in FIG. 22A, portions 2122′ of respective levels of materials 2122 are exposed at contact openings 1665 at the locations where the portions of liners 1721 were removed.

FIG. 24A and FIG. 24B show memory device 1000 after conductive contacts 2465 are formed in contact openings 1665 (labeled in FIG. 23A). Forming conductive contacts 2465 can include forming (e.g., filling) a conductive material 2465M in contact openings 1665. As shown in FIG. 24A, conductive material 2465M of conductive contacts 2465 can contact respective levels of materials 2122 (e.g., contact portions 2122′ (FIG. 21A) of respective levels of materials 2122). As shown in FIG. 24A, some of the levels of materials 2122 can form part of respective control gates (e.g., the control gates associated with signals WL1₀, WL2₀, and WL3₀) of memory device 1000.

Conductive material 2465M can include metal (e.g., tungsten or other metals) or a combination of different conductive materials (e.g., different layers of conductive material). An example of the combination of different conductive materials of conductive contacts 2465 include titanium nitride (e.g., a layer of titanium nitride (TiN)) and tungsten (e.g., a layer of tungsten (W). A CMP process can be performed after conductive material (or conductive materials) 2465M of conductive contacts 2465 is formed.

FIG. 25A and FIG. 25B show memory device 1000 after conductive portions 2541 and 2542, data lines 2570, and conductive lines 2556 are formed. Data lines 2570 and signals BL can be similar to data lines 270₀ through 270_{N} and signals BL₀ through BL_{N}, respectively, of memory device 200 in FIG. 4. Conductive lines 2556 can be similar to conductive lines 656 of FIG. 6C. Thus, conductive lines 2556 can have respective lengths in the X-direction.

Conductive portions 2542 can be coupled with respective data lines 2570 (associated with signals BL) and respective pillars (memory cell pillars) 550. Conductive portions 2541 can be coupled with respective conductive lines 2556 and respective conductive contacts 2465. Conductive portions 2541 can be similar to conductive portions 641 of memory device of FIG. 6C.

The processes of forming memory device 1000 described above with reference to FIG. 10A through FIG. 25B can include other processes to form a complete memory device (e.g., memory device 1000). Such processes are omitted from the above description so as not to obscure the subject matter described herein. Improvements and benefits of memory device 1000 are similar to or the same as improvements and benefits of memory device 200 described above.

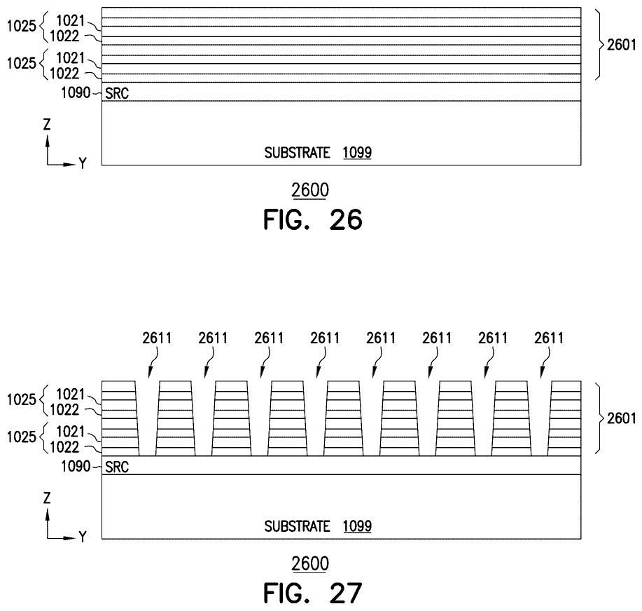

FIG. 26 through FIG. 31 show a side view of elements during processes of forming a memory device 2600 having multiple decks 2601, 2602, and 2603, according to some embodiments described herein. The processes of forming memory device 2600 can be similar to or the same as the processes of forming memory device 1000 (FIG. 10A through FIG. 25B). Differences between the processes of forming a memory devices 1000 and 2600 include the processes of forming openings 2611, 2612, and 2613 (FIG. 26 through FIG. 31).

FIG. 26 shows memory device 2600 after dielectric materials 1021 and 1022 are formed in tiers 1025. Dielectric materials 1021 and 1022 can be included in deck 2601 of memory device 2600.

FIG. 27 shows memory device 2600 after openings (e.g., holes) 2611 are formed. Forming openings 2611 can include removing a portion of dielectric materials 1021 and 1022 of deck 2601 at the locations of openings 2611.

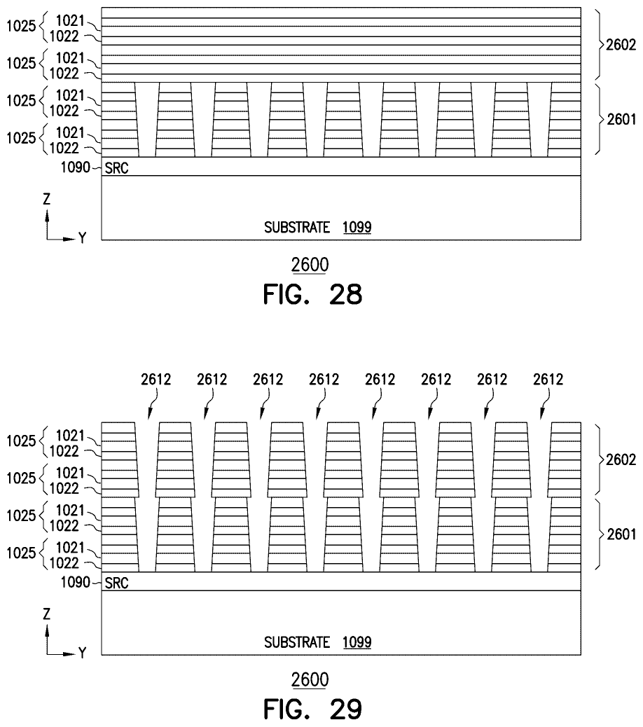

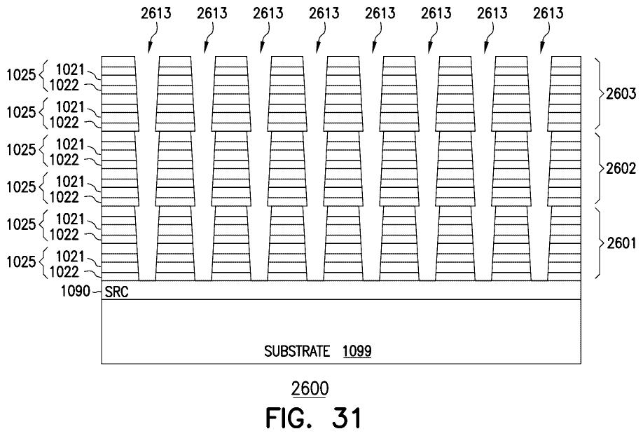

FIG. 28 shows memory device 2600 after dielectric materials 1021 and 1022 are formed in tiers 1025 included in deck 2602 of memory device 2600. The processes associated with FIG. 28 can include forming a sacrificial material (not shown) in openings 2611 before dielectric materials 1021 and 1022 of deck 2602 are formed. The sacrificial material can be subsequently removed (e.g., removed when openings 2613 in FIG. 31 are formed).

FIG. 29 shows memory device 2600 after openings (e.g., holes) 2612 are formed. Forming openings 2612 can include removing a portion of dielectric materials 1021 and 1022 of deck 2602 at the locations of openings 2612. As shown in FIG. 29, openings 2612 can be aligned (e.g., vertically aligned in the Z-direction) with respective openings 2611 formed in the processes associated with FIG. 27.

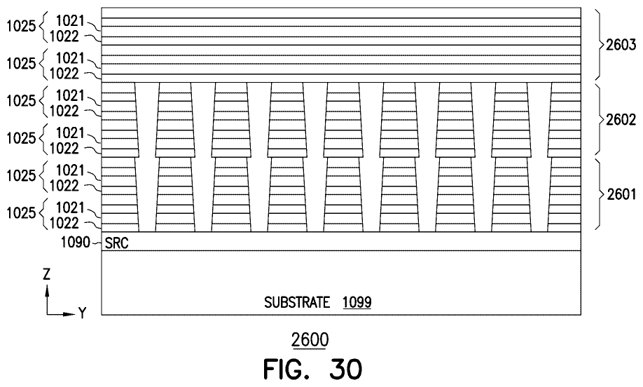

FIG. 30 shows memory device 2600 after dielectric materials 1021 and 1022 are formed in tiers 1025 included in deck 2603 of memory device 2600. The processes associated with FIG. 30 can include forming a sacrificial material (not shown) in openings 2612 before dielectric materials 1021 and 1022 of deck 2603 are formed. The sacrificial material can be subsequently removed (e.g., removed when openings 2613 in FIG. 31 are formed).

FIG. 31 shows memory device 2600 after openings (e.g., holes) 2613 are formed. Forming openings 2613 can include removing a portion of dielectric materials 1021 and 1022 of deck 2603 at the locations of openings 2613. Forming openings 2613 can also include removing sacrificial materials (not shown) in openings 2601 and 2602. As shown in FIG. 31, openings 2613 can be aligned (e.g., vertically aligned in the Z-direction) with respective openings 2611 and 2612 formed in the processes associated with FIG. 29 and FIG. 31.

The structure of memory device 2600 can be called a multi-deck structure (which includes decks 2601, 2602, and 2603). The process of forming memory device 2600 can continue with processes that are similar to or the same as the processes of forming memory device 1000 described above with reference to FIG. 11A through FIG. 25B. Thus, for simplicity, additional processes of forming memory device 2600 are omitted from the description herein. Improvements and benefits of memory device 2600 are similar to or the same as improvements and benefits of memory device 200 described above.

The combination of openings 2611, 2612, and 2613 (formed in the processes associated with FIG. 26 through FIG. 31) can be similar to openings 1144, 1150, and 1151 of FIG. 11A and FIG. 11B. In alternative processes of forming memory device 1000 (FIG. 10A through FIG. 25B), the structure of memory device 1000 can include the structure (e.g., multi-deck structure) of memory device 2600 (FIG. 26 through FIG. 31). Thus, forming openings 1144, 1150, and 1151 of FIG. 11A and FIG. 11B in the processes associated with FIG. 11A and FIG. 11B can include forming openings 2611, 2612, and 2613 described above with reference to FIG. 26 through FIG. 31.

The illustrations of apparatuses (e.g., memory devices 100, 200, 900, 1000, and 2600) and methods (e.g., method of forming memory devices 1000 and 2600) are intended to provide a general understanding of the structure of various embodiments and are not intended to provide a complete description of all the elements and features of apparatuses that might make use of the structures described herein. An apparatus herein refers to, for example, either a device (e.g., any of memory devices 100, 200, 900, 1000, and 2600) or a system (e.g., a computer, a cellular phone, or other electronic systems) that includes a device such as any of memory devices 100, 200, 900, 1000, and 2600.

Any of the components described above with reference to FIG. 1 through FIG. 31 can be implemented in a number of ways, including simulation via software. Thus, apparatuses, e.g., memory devices 100, 200, 900, 1000, and 2600, or part of each of these memory devices described above, may all be characterized as “modules” (or “module”) herein. Such modules may include hardware circuitry, single- and/or multi-processor circuits, memory circuits, software program modules and objects and/or firmware, and combinations thereof, as desired and/or as appropriate for particular implementations of various embodiments. For example, such modules may be included in a system operation simulation package, such as a software electrical signal simulation package, a power usage and ranges simulation package, a capacitance-inductance simulation package, a power/heat dissipation simulation package, a signal transmission-reception simulation package, and/or a combination of software and hardware used to operate or simulate the operation of various potential embodiments.

Memory devices 100, 200, 900, 1000, and 2600 may be included in apparatuses (e.g., electronic circuitry) such as high-speed computers, communication and signal processing circuitry, single- or multi-processor modules, single or multiple embedded processors, multicore processors, message information switches, and application-specific modules including multilayer, multichip modules. Such apparatuses may further be included as subcomponents within a variety of other apparatuses (e.g., electronic systems), such as televisions, cellular telephones, personal computers (e.g., laptop computers, desktop computers, handheld computers, tablet computers, etc.), workstations, radios, video players, audio players (e.g., MP3 (Motion Picture Experts Group, Audio Layer 3) players), vehicles, medical devices (e.g., heart monitor, blood pressure monitor, etc.), set top boxes, and others.

The embodiments described above with reference to FIG. 1 through FIG. 31 include apparatuses and methods of forming the apparatuses. One of the apparatuses includes a memory device, which includes levels of conductive materials interleaved with levels of dielectric materials; memory cell strings including respective pillars extending through the levels of conductive materials and the levels of dielectric materials; a dielectric structure including a length extending through the levels of conductive materials and the levels of dielectric materials; and a conductive contact contacting one of the levels of conductive materials, the conductive contact including a first portion and a second portion, and the dielectric structure including a portion the first portion of the conductive contact and the second portion of the conductive contact. Other embodiments including additional apparatuses and methods are described.

In the detailed description and the claims, the term “on” used with respect to two or more elements (e.g., materials), one “on” the other, means at least some contact between the elements (e.g., between the materials). The term “over” means the elements (e.g., materials) are in close proximity, but possibly with one or more additional intervening elements (e.g., materials) such that contact is possible but not required. Neither “on” nor “over” implies any directionality as used herein unless stated as such.

In the detailed description and the claims, the terms “first”, “second”, and “third,” etc. are used merely as labels, and are not intended to impose numerical requirements on their objects.

In the detailed description and the claims, a list of items joined by the term “at least one of” can mean any combination of the listed items. For example, if items A and B are listed, then the phrase “at least one of A and B” means A only; B only; or A and B. In another example, if items A, B, and C are listed, then the phrase “at least one of A, B and C” means A only; B only; C only; A and B (excluding C); A and C (excluding B); B and C (excluding A); or all of A, B, and C. Item A can include a single element or multiple elements. Item B can include a single element or multiple elements. Item C can include a single element or multiple elements.

In the detailed description and the claims, a list of items joined by the term “one of” can mean only one of the list items. For example, if items A and B are listed, then the phrase “one of A and B” means A only (excluding B), or B only (excluding A). In another example, if items A, B, and C are listed, then the phrase “one of A, B and C” means A only; B only; or C only. Item A can include a single element or multiple elements. Item B can include a single element or multiple elements. Item C can include a single element or multiple elements.

The above description and the drawings illustrate some embodiments of the inventive subject matter to enable those skilled in the art to practice the embodiments of the inventive subject matter. Other embodiments may incorporate structural, logical, electrical, process, and other changes. Examples merely typify possible variations. Portions and features of some embodiments may be included in, or substituted for, those of others. Many other embodiments will be apparent to those of skill in the art upon reading and understanding the above description.

What is claimed is:

1. An apparatus comprising:
levels of conductive materials interleaved with levels of dielectric materials;
memory cell strings including respective pillars extending through the levels of conductive materials and the levels of dielectric materials;
a dielectric structure including a length extending through the levels of conductive materials and the levels of dielectric materials; and
a conductive contact contacting one of the levels of conductive materials, the conductive contact including a first portion and a second portion, and the dielectric structure including a portion between the first portion of the conductive contact and the second portion of the conductive contact.

2. The apparatus of claim 1, further comprising:
an additional dielectric structure including length extending through the levels of conductive materials and the levels of dielectric materials, wherein the conductive contact is a first conductive contact contacting a first level of the levels of conductive materials; and
a second conductive contact contacting a second level of the levels of conductive materials, wherein the second conductive contact including a first portion and a second portion, and the additional dielectric structure including a portion between the first portion of the second conductive contact and the second portion of the second conductive contact.

3. The apparatus of claim 2, wherein:
the first level of the levels of conductive materials includes a first edge; and
the second level of the levels of conductive materials includes a second edge;
the dielectric structure is between a pillar of the pillars and each of the first edge and the second edge; and
the dielectric structure is between the pillar of the pillars and each of the first edge and the second edge.

4. The apparatus of claim 2, wherein the dielectric structure includes an end portion extends passed the first level of the levels of conductive materials.

5. The apparatus of claim 2, further comprising:
a first dielectric liner between the first conductive contact and the first level of the levels of conductive materials; and
a second dielectric liner between the second conductive contact and each of the first level of the levels of conductive materials and the second level of the levels of conductive materials.

6. The apparatus of claim 1, wherein the conductive contact is part of an access line associated with the memory cell strings.

7. An apparatus comprising:
tiers including levels of dielectric materials and levels and conductive materials interleaved with the levels of dielectric materials, the tiers including memory cells and control gates associated with the memory cells;
a dielectric structure including length in a direction from a first tier of the tiers to a second tier of the tiers; and
a conductive contact contacting a control gate associated with the first tier, wherein the conductive contact includes a portion directly over a portion of the dielectric structure.

8. The apparatus of claim 7, wherein the conductive contact surrounds at least a portion of the dielectric structure.

9. The apparatus of claim 7, further comprising a dielectric liner, wherein part of the conductive contact is between the dielectric liner and a portion of the dielectric structure.

10. The apparatus of claim 7, wherein further comprising an additional dielectric structure adjacent the conductive contact and including length in the direction from the first tier of the tiers to the second tier of the tiers, wherein the length of the additional dielectric structure is greater than the length of the dielectric structure.

11. The apparatus of claim 1, further comprising:
an additional dielectric structure including length in the direction from the first tier of the tiers to the second tier of the tiers; and
an additional conductive contact contacting an additional control gate associated with the second tier, wherein the additional conductive contact includes a portion directly over a portion of the additional dielectric structure.

12. The apparatus of claim 11, wherein the additional conductive contact surrounds a portion of the additional dielectric structure.

13. The apparatus of claim 11, wherein:
the dielectric structure extends through a first portion of the first control gate and a first portion of the second control gate; and
the additional dielectric structure extends through a second portion of the first control gate and a second portion of the second control gate.

14. The apparatus of claim 13, wherein:
the dielectric structure contacts the first portion of the first control gate and the first portion of the second control gate; and
the additional dielectric structure contacts the second portion of the first control gate and second portion of the second control gate.

15. A method comprising:
forming a memory cell string of a memory device including forming a pillar of the memory cell string in which the pillar including a length extending through different levels of materials of the memory device;
forming a dielectric pillar through the different levels of materials of the memory device; and
forming a conductive contact associated with a control gate associated with the memory cell string including forming the conductive contact directly over a dielectric pillar.

16. The method of claim 15, wherein forming the conductive contact includes:
forming a contact opening in a portion of the different levels of materials;
forming a dielectric liner in the contact opening;
forming a material in the contact opening;
replacing selected levels of the different levels of materials with respective levels of conductive materials;
removing the material in the contact opening;
removing a portion of the dielectric liner to expose a portion of a selected level of the levels of conductive materials, wherein at least a portion of the dielectric pillar is exposed at the contact opening; and
forming a conductive material in the contact opening over the portion of the selected level of the levels of conductive materials.

17. The method of claim 15, wherein at least a portion of the dielectric pillar is performed before forming the memory cell string.

18. The method of claim 16, wherein the selected levels of the different levels of materials include silicon nitride.

19. The method of claim 15, wherein the dielectric pillar includes a dielectric material different from the different levels of materials.

20. The method of claim 19, wherein forming the dielectric pillar includes:
forming a first opening through first deck of materials;
forming a second deck of materials over the first deck of materials;
forming a second opening through second deck of materials; and
forming the pillar at the location of the first opening and the location of the second opening.
